(19) United States
(12) Patent Application Publication
(10) Pub. No.: US 2024/0351408 A1
(43) Pub. Date: Oct. 24, 2024

(54) LIGHT-BLOCKING DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Yosuke TSUKAMOTO, Atsugi (JP); Koji KUSUNOKI, Isehara (JP); Shuhei YOSHITOMI, Ayase (JP); Akio ENDO, Atsugi (JP); Ryota TAJIMA, Isehara (JP)

(21) Appl. No.: 18/684,258

(22) PCT Filed: Aug. 22, 2022
(86) PCT No.: PCT/IB2022/057827

§ 371 Date: Feb. 16, 2024

(30) Foreign Application Priority Data
Aug. 27, 2021 (JP) 2021-139174
Sep. 15, 2021 (JP) 2021-149946

(51) Int. Cl. B60J 3/02; B60K 35/22; H02S 20/30; H02S 30/20

(52) U.S. Cl. CPC B60J 3/0243; B60K 35/22; H02S 20/30; H02S 30/20; B60K 2360/46; B60K 2360/777; B60K 2360/816

(57) ABSTRACT

A light-blocking device that includes a display device is provided. A method for unfolding a light-blocking device that includes a display device is provided. The light-blocking device is used for a vehicle. The light-blocking device includes a light-blocking portion, a storage portion, and a driving means. The light-blocking portion includes a display portion on a surface on the inside of the vehicle. The storage portion is positioned in a roof portion of the vehicle. The driving means has a first function of unfolding the light-blocking portion in a first position, a second function of unfolding the light-blocking portion in a second position, and a third function of storing the light-blocking portion in a third position inside the storage portion. The first position is a position where the light-blocking portion does not obstruct driver's forward vision. The second position is a position where the light-blocking portion covers 80% or higher of the area of a windshield of the vehicle.

### TECHNICAL FIELD

One embodiment of the present invention relates to a moving object. One embodiment of the present invention relates to a vehicle. One embodiment of the present invention relates to a light-blocking device of a moving object such as a vehicle. Another embodiment of the present invention relates to a method for controlling a light-blocking device of a moving object such as a vehicle. Another embodiment of the present invention relates to a display device included in a light-blocking device of a moving object such as a vehicle. Another embodiment of the present invention relates to a lighting device included in a light-blocking device of a moving object such as a vehicle. Another embodiment of the present invention relates to a power generation device included in a light-blocking device of a moving object such as a vehicle.

Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a vehicle, a semiconductor device, a display device, a light-emitting apparatus, a lighting device, a power storage device, a memory device, an operation method thereof, and a manufacturing method thereof.

Note that although a vehicle is given above as an example of a moving object, the moving object is not limited to a vehicle. Examples of moving objects include a train, a monorail train, a ship, and a flying object (a helicopter, an airplane, and a rocket). In addition, examples of vehicles include a motor vehicle, a bus, and a truck.

### BACKGROUND ART

In order to inhibit a rise in internal temperature of a vehicle during parking particularly in strong sunlight of the daytime, various types of sunshades have been proposed. In addition, due to diversification of modes of traveling and camping, spending the night in a vehicle has been conducted in many cases as one mode of staying, and measures to prevent a peek into the inside of the vehicle during spending the night in the vehicle have been required.

As a sunshade for covering a vehicle's window, a detachable sunshade that is fixed with a suction cup is sometimes used. However, the sunshade with such a structure is complicated to attach and requires a storage location after detachment. Therefore, providing an unfoldable and storable light-blocking device in a vehicle has been proposed (Patent Document 1).

In addition, owing to the progress of information networks and the progress of communication technologies, for example, video information that are available in vehicles (television broadcasting, video streaming service, and the like) have been increased.

Furthermore, owing to the progress of autonomous driving technologies for vehicles (JASO TP18004 (2018)), autonomous driving systems at Level 3 (conditionally autonomous driving) have been put in practical use, and autonomous driving systems at Level 4 (highly autonomous driving) and Level 5 (fully autonomous driving) might be put in practical use in the future. A vehicle during such autonomous driving needs to include a display device that allows users to enjoy video information in the vehicle and work remotely in the vehicle, for example. It is desirable that the display device included in the vehicle be a display device with a larger screen; therefore, providing a large-sized unfoldable and storable display device in the vehicle has been proposed (Patent Document 2).

### REFERENCE

### Patent Document

[Patent Document 1] Japanese Published Patent Application No. 2002-67688
[Patent Document 2] PCT International Publication No. 2016/020808

### SUMMARY OF THE INVENTION

### Problems to be Solved by the Invention

Patent Document 1 discloses an example in which a roof portion of a vehicle includes a storage portion for a light-blocking device. However, the light-blocking device disclosed in Patent Document 1 has only a function of the light-blocking device and does not include a means for displaying an image or the like.

In addition, the light-blocking device disclosed in Patent Document 1 is intended to be used in a rear window, and its structure is difficult to use for a vehicle including a rear-view mirror (also referred to as an inside rear-view mirror) in a windshield. Here, it is possible to employ a structure where different light-blocking devices are used for a driver seat side and a passenger seat side. However, a gap is generated between the different light-blocking devices that are used for the driver seat side and the passenger seat side; therefore, such a structure is difficult to sufficiently block the windshield from light. Furthermore, air heated between the windshield and the light-blocking device is diffused into the vehicle from the gap between the light-blocking devices; therefore, the internal temperature of the vehicle is easily increased.

In addition, in the case where a display device is placed on a surface of the light-blocking device on the inner side of the vehicle (also referred to as a surface on the inside of the vehicle) or in the case where the surface of the light-blocking device that is on the inside of the vehicle is used as a projection surface of a projector device, display quality is decreased in the structure where the different light-blocking devices are used for the driver seat side and the passenger seat side.

Furthermore, as the display device disclosed in Patent Document 2, it is possible to provide a display device with a large screen in a vehicle; however, Patent Document 2 does not disclose a function of a light-blocking device included in the vehicle.

In view of the above, an object of one embodiment of the present invention is to provide a light-blocking device that includes a display device. Another object is to provide a method for unfolding a light-blocking device that includes a display device. Another object is to provide a light-blocking device whose space from a windshield of a vehicle can be made small when used for the windshield, as a light-blocking device that includes a display device. Another object is to provide a display device that can be included in a light-blocking device. Another object is to provide a display method of a display device that can be included in a light-blocking device.

Another object of one embodiment of the present invention is to provide a light-blocking device that can be unfolded and stored by, for example, an electrically-driven driving means. Another object of one embodiment of the present invention is to provide a light-blocking device used for a windshield of a vehicle. Another object is to provide a light-blocking device where different light-blocking devices are not used for a driver seat side and a passenger seat side, as a light-blocking device used for a windshield of a vehicle. Another object is to provide a light-blocking device whose space from a windshield of a vehicle can be made small as a light-blocking device used for the windshield.

Note that the description of these objects does not preclude the presence of other objects. One embodiment of the present invention does not need to achieve all these objects. In addition, objects other than the above will be apparent from the description of the specification and the like, and objects other than the above can be derived from the description of the specification and the like.

### Means for Solving the Problems

One embodiment of the present invention is a light-blocking device used for a vehicle. The light-blocking device includes a light-blocking portion, a storage portion, and a driving means. The light-blocking portion includes a display portion on a surface on the inside of the vehicle. The storage portion is positioned in a roof portion of the vehicle. The driving means has a first function of unfolding the light-blocking portion in a first position, a second function of unfolding the light-blocking portion in a second position, and a third function of storing the light-blocking portion in a third position inside the storage portion. The first position is a position where the light-blocking portion does not obstruct driver's forward vision. The second position is a position where the light-blocking portion covers 80% or higher of the area of a windshield of the vehicle.

In the light-blocking device described above, it is preferable that the light-blocking portion include a reflective layer on a surface on the outside of the vehicle, that the reflective layer include an aluminum layer and a silicon nitride layer over the aluminum layer, and that reflectance of the reflective layer be higher than or equal to 80%.

In any one of the light-blocking devices described above, it is preferable that the light-blocking portion include a solar battery on a surface on the outside of the vehicle and that a silicon-type solar battery, a CIGS-type solar battery, or a perovskite-type solar battery be included as the solar battery.

In any one of the light-blocking devices described above, it is preferable that the display portion be electrically connected to an image output portion, that the image output portion include an image processing portion for performing correction processing on an image output to the display portion, and that the image processing portion have a function of extending the image in a vertical direction and correcting the image into an image with a trapezoidal shape where the left-right width of a lower part is wide.

In any one of the light-blocking devices described above, the light-blocking portion includes a spring portion connected to the display portion and a support portion connected to the spring portion. The support portion is connected to a movable portion included in the driving means inside a pillar of the vehicle. The movable portion is connected to a first winding portion and a second winding portion. In the first function, the second function, and the third function, either one or both the first winding portion and the second winding portion perform a rotation operation.

In any one of the light-blocking devices described above, it is preferable that the storage portion include a transmitting portion and that the transmitting portion and the display portion overlap with each other when the light-blocking portion is placed in the third position.

Another embodiment of the present invention is a light-blocking device used for a vehicle. The light-blocking device includes a light-blocking portion, a storage portion, and a driving means. The storage portion is positioned in a roof portion of the vehicle. The light-blocking portion includes a first portion including the opening portion, a second portion joined to the first portion, and a third portion joined to the second portion. The size of the opening portion is larger than the size of a rear-view mirror included in the vehicle. The driving means includes a first mechanism for unfolding the light-blocking portion downwards from the roof portion in a first state where the first portion, the second portion, and the third portion overlap with one another, a second mechanism for inclining the light-blocking portion while being in the first state substantially parallel to a windshield included in the vehicle without contact with the rear-view mirror, and a third mechanism for unfolding the light-blocking portion in an inclined state so that the second portion and the third portion are substantially parallel to the windshield.

### Effect of the Invention

According to one embodiment of the present invention, it is possible to provide a light-blocking device that includes a display device used for a moving object such as a vehicle. In addition, it is possible to provide a moving object such as a vehicle that is provided with a light-blocking device including a display device. In addition, it is possible to provide a method for unfolding a light-blocking device that includes a display device. Furthermore, it is possible to provide a light-blocking device that can be unfolded and stored by, for example, an electrically-driven driving means. Furthermore, it is possible to provide a display device that can be included in a light-blocking device. Moreover, it is possible to provide a display method of a display device that can be included in a light-blocking device.

According to another embodiment of the present invention, it is possible to provide a light-blocking device used for a windshield of a vehicle. In addition, it is possible to provide a light-blocking device where different light-blocking devices are not used for a driver seat side and a passenger seat side, as a light-blocking device used for a windshield of a vehicle. Furthermore, it is possible to provide a light-blocking device whose space from a windshield of a vehicle can be made small as a light-blocking device used for the windshield. Moreover, it is possible to provide a structure where a display device is included in the light-blocking device.

According to another embodiment of the present invention, it is possible to provide a light-blocking device used for a vehicle including a rear-view mirror in a windshield. In addition, it is possible to provide a light-blocking device where different light-blocking devices are not used for a driver seat side and a passenger seat side, as a light-blocking device used for a vehicle including a rear-view mirror in a windshield. Furthermore, it is possible to provide a light-blocking device whose space from a windshield can be made small as a light-blocking device used for a vehicle including a rear-view mirror in the windshield. Moreover, it is possible to provide a structure where a display device is included in the light-blocking device.

Note that the description of these effects does not preclude the presence of other effects. Note that one embodiment of the present invention does not need to have all these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A and FIG. 1B are diagrams illustrating a structure example of a light-blocking device according to an embodiment.

FIG. 2A to FIG. 2D are diagrams illustrating a structure example of the light-blocking device according to the embodiment.

FIG. 3A and FIG. 3B are diagrams illustrating structure examples of the light-blocking device according to the embodiment.

FIG. 4A to FIG. 4C are diagrams illustrating a structure example of the light-blocking device according to the embodiment.

FIG. 5A to FIG. 5C are diagrams illustrating a structure example of the light-blocking device according to the embodiment.

FIG. 6A and FIG. 6B are diagrams illustrating a structure example of the light-blocking device according to the embodiment.

FIG. 7A to FIG. 7E are diagrams showing image correction according to an embodiment.

FIG. 8A and FIG. 8B are diagrams illustrating a structure example of the light-blocking device according to the embodiment.

FIG. 9A1 to FIG. 9D2 are diagrams illustrating a structure example of the light-blocking device according to the embodiment.

FIG. 10A1 to FIG. 10D2 are diagrams illustrating a structure example of the light-blocking device according to the embodiment.

FIG. 11A to FIG. 11C are diagrams illustrating structure examples of the light-blocking device according to the embodiment.

FIG. 12A to FIG. 12C are diagrams illustrating a structure example of a display device.

FIG. 13A to FIG. 13F are diagrams illustrating pixel structure examples.

FIG. 14 is a diagram illustrating a structure example of a display device.

FIG. 15A and FIG. 15B are diagrams illustrating a structure example of the display device.

FIG. 16A to FIG. 16F are diagrams illustrating structure examples of light-emitting devices.

FIG. 17A and FIG. 17B are diagrams illustrating structure examples of light-receiving devices.

FIG. 17C to FIG. 17E are diagrams illustrating structure examples of a display device.

FIG. 18A and FIG. 18B are top views illustrating structure examples of display panels.

FIG. 19A to FIG. 19C are top views illustrating structure examples of the display panels.

FIG. 20A and FIG. 20B are cross-sectional views illustrating structure examples of a display panel.

FIG. 21A to FIG. 21C are diagrams illustrating a display panel and a display device in Example 1.

FIG. 22A and FIG. 22B are diagrams illustrating the display device in Example 1.

FIG. 23 is a photograph of the appearance of the display device in Example 1.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and description thereof is not repeated. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification are used in order to avoid confusion among components and do not limit the number of components.

Note that the term “film” and the term “layer” can be interchanged with each other in some cases. For example, the term “conductive layer” can be replaced with the term “conductive film” in some cases. For another example, the term “insulating film” can be replaced with the term “insulating layer” in some cases.

### Embodiment 1

In this embodiment, structure examples of a light-blocking device according to one embodiment of the present invention will be described with reference to diagrams.

### Structure Example 1 of Light-Blocking Device

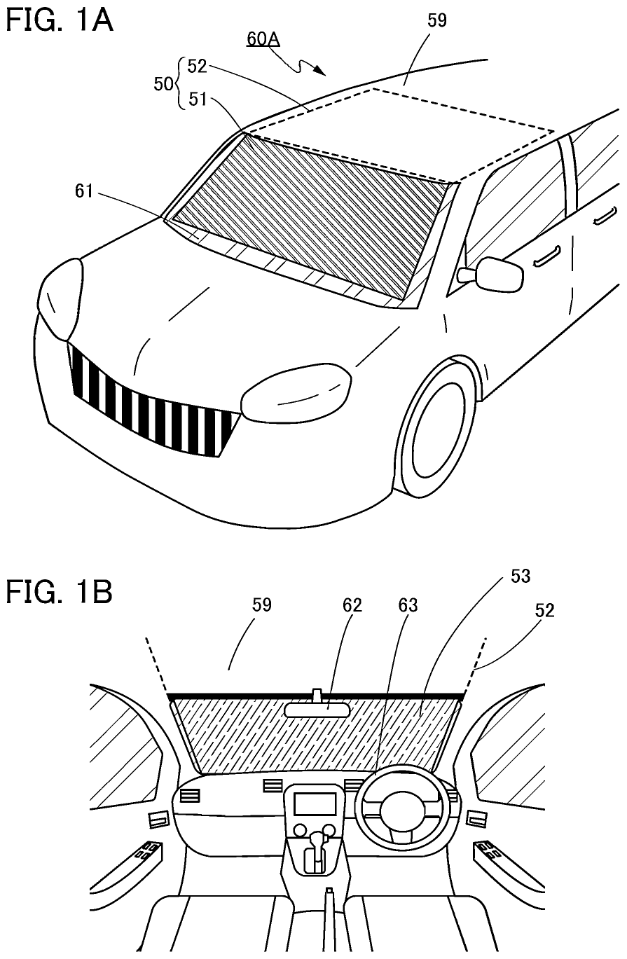

FIG. 1A and FIG. 1B illustrate an example of a light-blocking device according to one embodiment of the present invention. FIG. 1A illustrates a schematic bird's eye view of the appearance of a vehicle 60A as an example of a vehicle including the light-blocking device according to one embodiment of the present invention. FIG. 1B illustrates a perspective view of the inside of the vehicle 60A. Here, an example is shown in which a light-blocking device 50 including a light-blocking portion 51 that is unfolded around a windshield 61 inside the vehicle 60A is placed in a roof portion 59 of the vehicle 60A.

As illustrated in FIG. 1A, the light-blocking device 50 includes the light-blocking portion 51 and a storage portion 52. The storage portion 52 has a function of storing the light-blocking portion 51 and a function of unfolding the light-blocking portion 51. In addition, as illustrated in FIG. 1B, a display portion 53 is preferably provided on a surface of the light-blocking portion 51 on the inner side of the vehicle. Furthermore, the light-blocking portion 51 and the display portion 53 preferably have flexibility.

The light-blocking portion 51 preferably includes a flexible substrate (also referred to as a flexible sheet, film, or screen). In addition, in the case where the light-blocking portion 51 includes the display portion 53, the display portion 53 may be used as the substrate of the light-blocking portion 51. Note that for the flexible substrate, a flexible material such as a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (nylon, aramid, or the like), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example.

The light-blocking portion 51 preferably has a function of blocking light from the outside of the vehicle on a surface on the outer side of the vehicle (also referred to as a surface on the outside of the vehicle), further preferably has a function of reflecting light from the outside of the vehicle. In the case where the light-blocking portion 51 has a function of blocking light from the outside of the vehicle, visible light transmittance of the light-blocking portion 51 is preferably lower than or equal to 20%, further preferably lower than or equal to 10%, still further preferably lower than or equal to 5%, yet further preferably 0%.

In addition, in the case where the light-blocking portion 51 has a function of reflecting light from the outside of the vehicle, the light-blocking portion 51 can include a reflective layer using a metal layer of, for example, aluminum, titanium, silver, an aluminum-titanium alloy, an aluminum-neodymium alloy, a silver-neodymium alloy, or the like. As a method for forming the metal layer, an evaporation method, a sputtering method, a CVD (Chemical Vapor Deposition) method, a PLD (Pulsed Laser Deposition) method, an ALD (Atomic Layer Deposition) method, an MCVD (Metal CVD) method, an MOCVD (Metal Organic CVD) method, or the like can be used. The metal layer may be directly formed on the substrate of the light-blocking portion 51, or the metal layer may be formed over another substrate and then attached onto the light-blocking portion 51.

Alternatively, the reflective layer may include a transparent inorganic layer of silicon oxide, silicon nitride, silicon oxynitride, silicon nitride oxide, or the like over the metal layer of aluminum or the like. In the case where the reflective layer includes an inorganic layer over the metal layer, the inorganic layer prevents degradation (oxidation or the like) of a surface of the metal layer and thus can inhibit a decrease in reflectance of the reflective layer, which is preferable. As a method for forming the inorganic layer, a liquid phase method such as a sol-gel method as well as an evaporation method, a sputtering method, or a gas phase method such as a CVD method, a PLD method, or an ALD method can be used. As the reflective layer that includes the inorganic layer over the metal layer, it is possible to use a structure where a silicon nitride layer is provided over an aluminum layer, for example. Visible light reflectance of the reflective layer is preferably higher than or equal to 50%, further preferably higher than or equal to 80%, still further preferably higher than or equal to 90%, yet further preferably higher than or equal to 95%.

Alternatively, the light-blocking portion 51 may include a power generation device. A photoelectric transducer such as a solar battery, or a temperature difference power generation device can be used as the power generation device, for example. A photoelectric transducer such as a solar battery is preferably provided on a surface of the light-blocking portion 51 on the outer side of the vehicle. In addition, since the light-blocking portion 51 preferably has flexibility, the power generation device included in the light-blocking portion 51 also preferably has flexibility. A thin-film type solar battery may be used as a flexible solar battery, for example. A silicon-type solar battery using silicon such as amorphous silicon, polysilicon, or single crystal silicon is preferably used as a thin-film type solar battery. Alternatively, a CIGS-type solar battery using a semiconductor material CIGS made of copper (Cu), indium (In), gallium (Ga), or selenium (Se) is preferably used. Alternatively, a perovskite-type solar battery using a material having a perovskite structure (NH₃CH₃PbI₃ or the like) is preferably used.

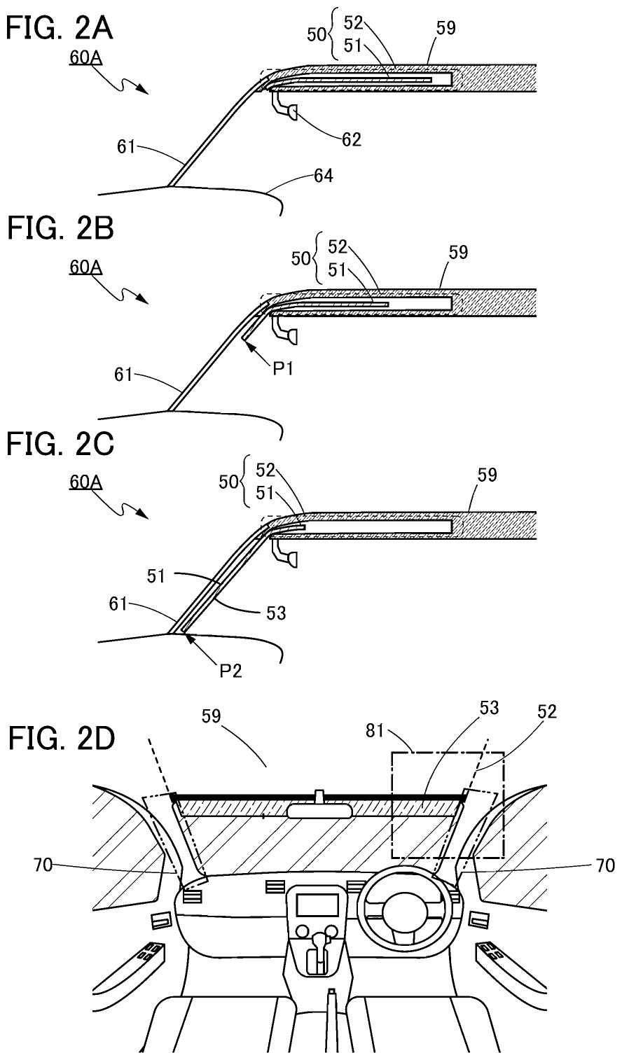

FIG. 2A to FIG. 2D are diagrams illustrating unfolding and storage of the light-blocking device 50. FIG. 2A is a cross-sectional schematic diagram showing a state where the light-blocking portion 51 is stored in the storage portion 52 in the light-blocking device 50 included in the vehicle 60A. FIG. 2B and FIG. 2C are cross-sectional schematic diagrams each showing a state where the light-blocking portion 51 is unfolded to approach the windshield 61 in the light-blocking device 50 included in the vehicle 60A. As illustrated in FIG. 2A, when the light-blocking portion 51 is stored in the storage portion 52 in the roof portion 59 of the vehicle 60A, the internal space of the roof portion 59 that has been hardly used conventionally can be effectively utilized, which is preferable.

As illustrated in FIG. 2B and FIG. 2C, the light-blocking device 50 can have a plurality of unfolding positions as the unfolding positions of a lower end portion of the light-blocking portion 51. For example, in a state where the lower end portion of the light-blocking portion 51 is unfolded in a first unfolding position P1 as illustrated in FIG. 2B, the light-blocking portion 51 can be utilized as a sun visor during driving by a driver. FIG. 2D is a schematic diagram showing the state where the lower end portion of the light-blocking portion 51 is unfolded in the first unfolding position P1 as illustrated in FIG. 2B when seen from the inside of the vehicle 60A. The light-blocking portion 51 does not obstruct driver's forward vision in the first unfolding position P1; thus, the driver can drive the vehicle 60A in this state. For example, as the first unfolding position P1 that does not obstruct the driver's forward vision, the light-blocking portion 51 is preferably unfolded so that the lower end of the light-blocking portion 51 is positioned within 50% or lower, 30% or lower, or 20% or lower of the vertical length of the windshield 61 from the upper end of the windshield 61 when seen from the driver. In the case where the light-blocking portion 51 includes the display portion 53 on the inner side of the vehicle as illustrated in FIG. 2D, in the state where the light-blocking portion 51 is unfolded in the first unfolding position P1, the display portion 53 can display video taken by a camera provided outside a vehicle body and can also display a variety of information to support driving, such as map information, traffic information, vehicle's positional information, a route to a destination, distance, traveling direction, estimated arrival time, time, speed, orientation, temperature, humidity, atmospheric pressure, an inclination angle, and altitude.

In addition, in a state where the light-blocking portion 51 is unfolded in a second unfolding position P2 as illustrated in FIG. 2C, the light-blocking portion 51 is positioned to overlap with the upper end to the lower end of the windshield 61. Therefore, the light-blocking portion 51 is unfolded in the second unfolding position P2 when the vehicle is stopped, parked, moved backward, or driven with an autonomous driving system at Level 4 (highly autonomous driving) and Level 5 (fully autonomous driving), for example. Note that as the state where the light-blocking portion 51 is unfolded in the second unfolding position P2, the light-blocking portion 51 preferably covers 80% or higher of the area of the windshield 61, further preferably covers 90% or higher of the area of the windshield 61, still further preferably covers 95% or higher of the area of the windshield 61, yet further preferably covers 100% of the area of the windshield 61.

In the case where the light-blocking portion 51 includes the display portion 53 on the inner side of the vehicle as illustrated in FIG. 2C, the display portion 53 can display video taken by the camera provided outside the vehicle body and can also display a variety of information to support driving, such as map information, traffic information, vehicle's positional information, a route to a destination, distance, traveling direction, estimated arrival time, time, speed, orientation, temperature, humidity, atmospheric pressure, an inclination angle, and altitude. In addition, the display portion 53 can display television broadcasting, video stored in a variety of media, video transmitted from an information terminal such as a laptop PC, a tablet terminal, a cellular phone, or a smartphone, a portable game machine, or the like, for example.

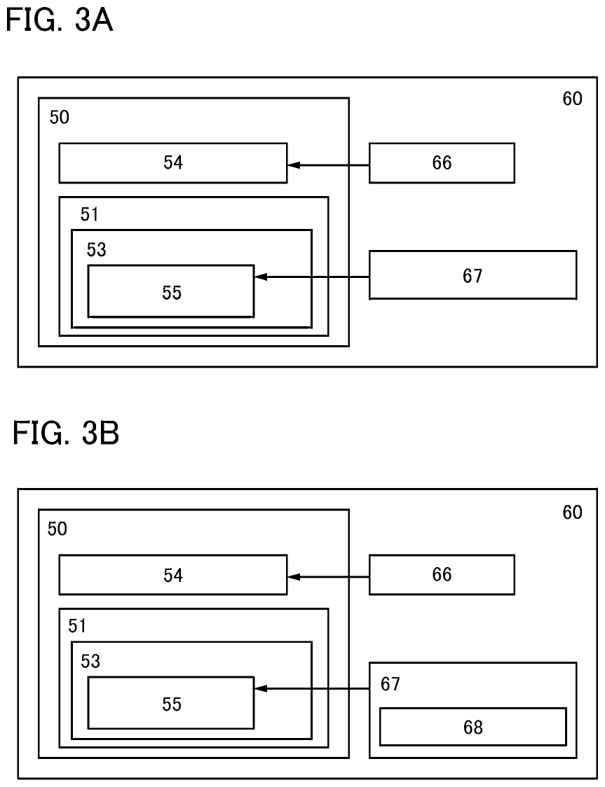

FIG. 3A and FIG. 3B each illustrate an example of a block diagram of a vehicle 60 into which the light-blocking device 50 including the display portion 53 is incorporated. The vehicle 60 includes the light-blocking device 50, an image output portion 67, an operating portion 66, and the like, for example.

As illustrated in FIG. 3A, the light-blocking device 50 includes the light-blocking portion 51, a driving means 54, and the like, the light-blocking portion 51 includes the display portion 53, and the display portion 53 includes a display panel 55. The display panel 55 preferably has flexibility. In the case where the display panel 55 has flexibility, the display panel 55 can become deformed into a state where its display surface is flat or curved, a mode in which the display panel 55 is wound and stored, or a mode in which the display panel 55 is folded and stored. Note that a display device that will be described in Embodiment 2 is preferably used as the display panel 55.

In addition, the driving means 54 included in the light-blocking device 50 can unfold and store the light-blocking portion 51 included in the display portion 53. The driving means 54 can be operated with the operating portion 66, for example.

### Unfolding and Storage Method 1 of Light-Blocking Device

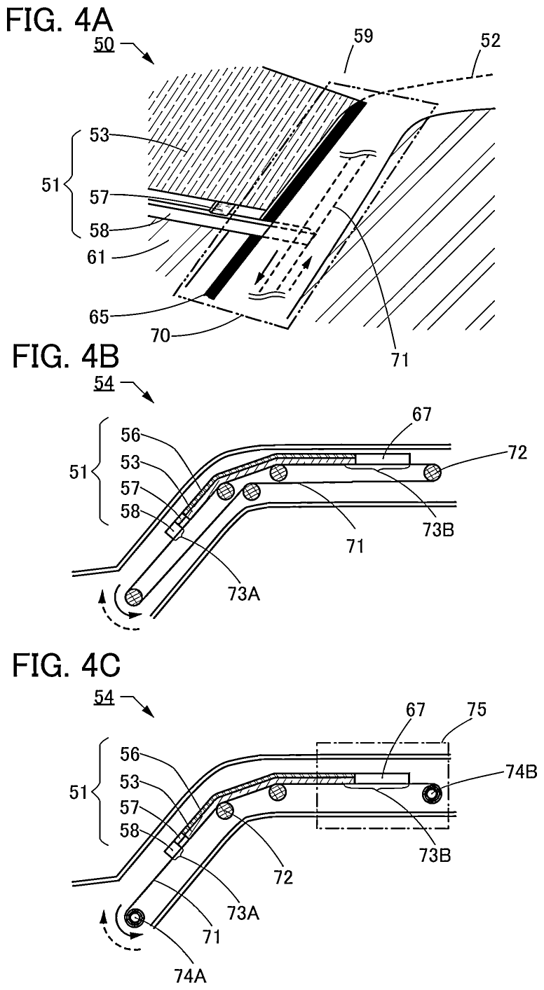

Examples of an unfolding and storage method of the light-blocking device 50 and the driving means 54 are described using FIG. 4A to FIG. 6B.

FIG. 4A is a schematic diagram of a region 81 indicated by a dashed dotted line in FIG. 2D. The light-blocking portion 51 includes the display portion 53, a spring portion 57, and a support portion 58. The support portion 58 is connected to a movable portion 71 that is to be described later and is included in the driving means 54 inside an opening portion 65 of a pillar 70. Note that the pillar 70 is a portion of the vehicle that is indicated by a dashed double-dotted line in each of FIG. 2D and FIG. 4A. The movable portion 71 has a function of performing an operation of unfolding the light-blocking portion 51 in the direction of a solid arrow in the figure and performing an operation of storing the light-blocking portion 51 in the direction of a broken arrow. In addition, the support portion 58 is connected to the display portion 53 through the spring portion 57. When the support portion 58 is connected to the display portion 53 through the spring portion 57, warpage of the display portion 53 can be inhibited at the time of unfolding the light-blocking portion 51. Note that although the case of using the spring portion 57 is described here, one embodiment of the present invention is not limited to a spring as long as constant force (tension) can be added toward the outside so that warpage of the display portion 53 does not occur. For example, an elastic body such as rubber may be used.

FIG. 4B and FIG. 4C are cross-sectional schematic diagrams of the roof portion 59 and the pillar 70 illustrated in FIG. 4A. The driving means 54 is described using FIG. 4B and FIG. 4C. In FIG. 4B, the driving means 54 includes the movable portion 71 and a plurality of guide portions 72. In addition, the movable portion 71 is connected to the support portion 58 in a fixing region 73A, the movable portion 71 is connected to part of the display portion 53 in a fixing region 73B, and the movable portion 71 is connected to the image output portion 67 in the fixing region 73B. One or more of the guide portions 72 are connected to a motor.

In FIG. 4B, the light-blocking portion 51 includes the display portion 53, a reflective layer 56, the spring portion 57, and the support portion 58 and has a region connected to the image output portion 67. The support portion 58 that is connected to the display portion 53 through the spring portion 57 is connected to the movable portion 71 in the fixing region 73A. In addition, the display portion 53 is connected to the movable portion 71 in the fixing region 73B on a side opposite to a side connected to the spring portion 57. The movable portion 71 is in contact with the plurality of guide portions 72, and one or more of the guide portions 72 are connected to the motor. The movable portion 71 moves in the direction of a solid arrow in the figure by a rotation operation of the motor to unfold the light-blocking portion 51, and moves in the direction of a broken arrow in the figure to store the light-blocking portion 51. In that case, by providing the fixing region 73A and the fixing region 73B as described above, even in the case where the movable portion 71 moves, constant force (tension) is added to the display portion 53; therefore, warpage of the display portion 53 can be inhibited.

In addition, the driving means 54 illustrated in FIG. 4C is an example of a driving means that is different from the driving means in FIG. 4B. In FIG. 4C, the driving means 54 includes the movable portion 71, the plurality of guide portions 72, and winding portions 74 (74A and 74B). Furthermore, the movable portion 71 is connected to the support portion 58 in the fixing region 73A, the movable portion 71 is connected to part of the display portion 53 in the fixing region 73B, and the movable portion 71 is connected to the image output portion 67 in the fixing region 73B. One or more of the winding portions 74 (74A and 74B) are connected to the motor.

In FIG. 4C, the light-blocking portion 51 includes the display portion 53, the reflective layer 56, the spring portion 57, and the support portion 58 and has a region connected to the image output portion 67. The support portion 58 that is connected to the display portion 53 through the spring portion 57 is connected to the movable portion 71 in the fixing region 73A. In addition, the display portion 53 is connected to the movable portion 71 in the fixing region 73B on a side opposite to a side connected to the spring portion 57. The movable portion 71 is connected to the winding portion 74A and the winding portion 74B, and at least one of the winding portion 74A and the winding portion 74B is connected to the motor. The movable portion 71 is in contact with the plurality of guide portions 72, moves in the direction of a solid arrow in the figure by a rotation operation of the motor to unfold the light-blocking portion 51, and moves in the direction of a broken arrow in the figure to store the light-blocking portion 51. In that case, by providing the fixing region 73A and the fixing region 73B as described above, even in the case where the movable portion 71 moves, constant force (tension) is added to the display portion 53; therefore, warpage of the display portion 53 can be inhibited.

Note that although the driving means 54 illustrated in FIG. 4B and FIG. 4C is preferably provided inside the pillar 70, the driving means 54 may be provided outside the pillar 70. In addition, although not illustrated, it is preferable to provide the driving means 54 both in the pillar 70 on the left side and the pillar 70 on the right side that are included in the vehicle 60. In addition, the spring portion 57 preferably connects the display portion 53 and the support portion 58 to each other in two or more locations without being limited to one location.

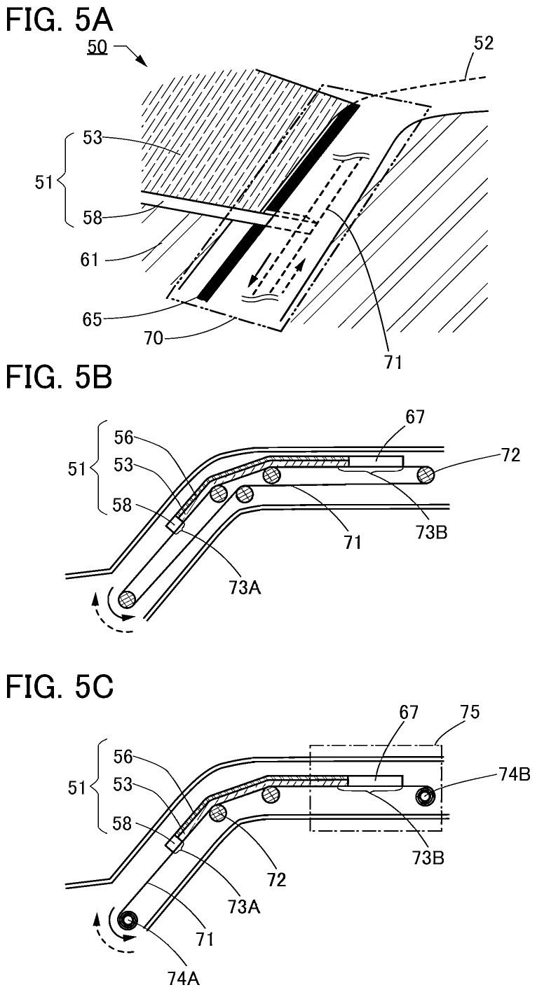

Although FIG. 4A to FIG. 4C show the example in which the support portion 58 is connected to the display portion 53 through the spring portion 57, a structure without including the spring portion 57 like an example shown in FIG. 5A to FIG. 5C may be employed.

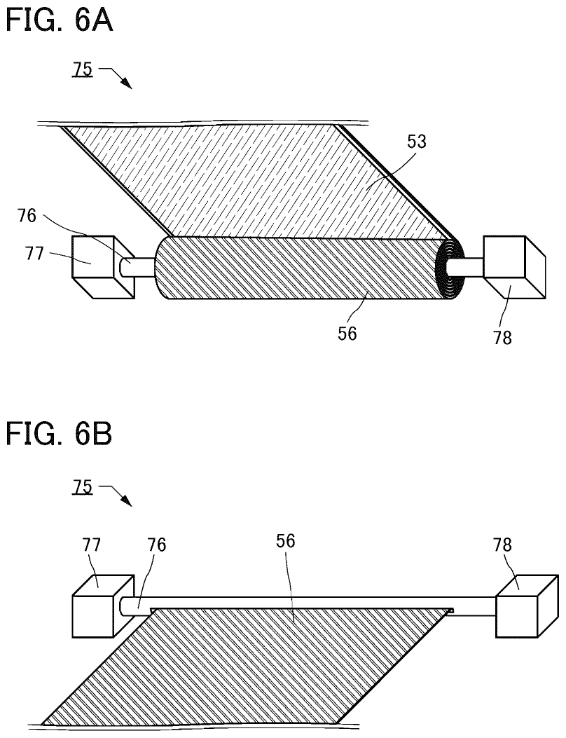

In addition, FIG. 6A and FIG. 6B illustrate a modification example of a region 75 in FIG. 4C and FIG. 5C. In FIG. 6A and FIG. 6B, an example is shown in which the light-blocking device 50 includes a rotation mechanism 77 that corresponds to the winding portion 74B in FIG. 4C and FIG. 5C and a shaft portion 76 and the image output portion 67 is included inside the shaft portion 76.

The thickness of the light-blocking portion 51 can be, for example, greater than or equal to 10 m and less than or equal to 5 mm, preferably greater than or equal to 20 m and less than or equal to 4 mm, further preferably greater than or equal to 50 m and less than or equal to 3 mm, typically greater than or equal to 100 m and less than or equal to 2 mm. As the thickness of the light-blocking portion 51 becomes smaller, the size of the light-blocking device 50 when the light-blocking portion 51 is wound can be made smaller. Meanwhile, when the light-blocking portion 51 is too thin, the light-blocking portion 51 becomes easily affected by wind or another factor, and the mechanical strength of the light-blocking portion 51 might be reduced. In addition, for example, when the light-blocking portion 51 has a moderate thickness of approximately greater than or equal to 0.5 mm and less than or equal to 5 mm, it is possible to inhibit a defect such as a wavy display surface of the light-blocking portion 51 even in the state where the light-blocking portion 51 is unfolded. Furthermore, an elastic material may be used for the light-blocking portion 51.

The shaft portion 76 has a function of fixing one end of the light-blocking portion 51. A ribbon cable that is electrically connected to the display portion 53 and the image output portion 67 that includes an FPC (Flexible Printed Circuit) and the like are placed in the shaft portion 76. Here, a connector and a wiring that are electrically connected to the image output portion 67 are preferably provided in the shaft portion 76. In addition, the shaft portion 76 preferably includes a circuit for supplying a signal and voltage to the light-blocking portion 51. Besides, the shaft portion 76 may include one or more of an antenna, a wireless receiver, a wireless transmitter, a power supply line, a battery, a printed circuit board mounted with an IC such as an arithmetic device and a memory device, an external connection port, and the like.

Here, as the diameter of the shaft portion 76 becomes smaller, the size of the light-blocking device 50 when the light-blocking portion 51 is wound can be made smaller. The diameter of the shaft portion 76 is determined depending on allowable curvature when the light-blocking portion 51 is bent. The diameter of the shaft portion 76 can be, for example, greater than or equal to 0.1 mm and less than or equal to 50 mm, preferably greater than or equal to 0.5 mm and less than or equal to 30 mm, further preferably greater than or equal to 1 mm and less than or equal to 20 mm, still further preferably greater than or equal to 2 mm and less than or equal to 10 mm. Warpage of the shaft portion 76 due to the weight of the light-blocking portion 51 can be inhibited when the diameter of the shaft portion 76 is greater than or equal to 0.1 mm. In addition, when the diameter of the shaft portion 76 is less than or equal to 50 mm, the size of the winding portion 74B can be made sufficiently small.

The rotation mechanism 77 has a function of rotating the shaft portion 76. A bearing portion 78 has a function of supporting the shaft portion 76. The rotation mechanism 77 has a structure in which power such as a motor and a gear or the like are combined to rotate the shaft portion 76, for example.

### <Display Portion of Light-Blocking Device>

As illustrated in FIG. 3A, the display portion 53 included in the light-blocking device 50 illustrated in FIG. 1B and the like includes the display panel 55, and the image output portion 67 can be connected to the display panel 55. Video and an image output from the image output portion 67 can be displayed on the display surface of the display panel 55. Video taken by the camera provided outside the vehicle body can be displayed on the display panel 55 through the image output portion 67, and a variety of information such as time, speed, orientation, temperature, humidity, atmospheric pressure, an inclination angle, and altitude as well as information such as map information, traffic information, vehicle's positional information, a route to a destination, distance, traveling direction, and estimated arrival time can be displayed on the display panel 55. In addition, when the image output portion 67 such as a media player for playing video information stored in a television broadcasting receiver (a tuner) or a memory device such as a CD, a DVD, or a memory card is connected to the light-blocking device 50, a variety of video of television broadcasting or the like can be also displayed on the display panel 55. Furthermore, when an information terminal such as a laptop PC, a tablet terminal, a cellular phone, or a smartphone, a portable game machine, or the like is connected to the image output portion 67 without wire or with wire, video or the like transmitted from the information terminal or the game machine can be also displayed on the display panel 55 through the image output portion 67.

The display panel 55 may have a function of a touch panel. In that case, an application and an icon or the like tied to an application operation are preferably displayed on the display panel 55. Accordingly, an intuitive operation can be facilitated. For example, moving, zooming in, zooming out, and the like of a map may be performed by a touch operation.

### <Image Correction Processing>

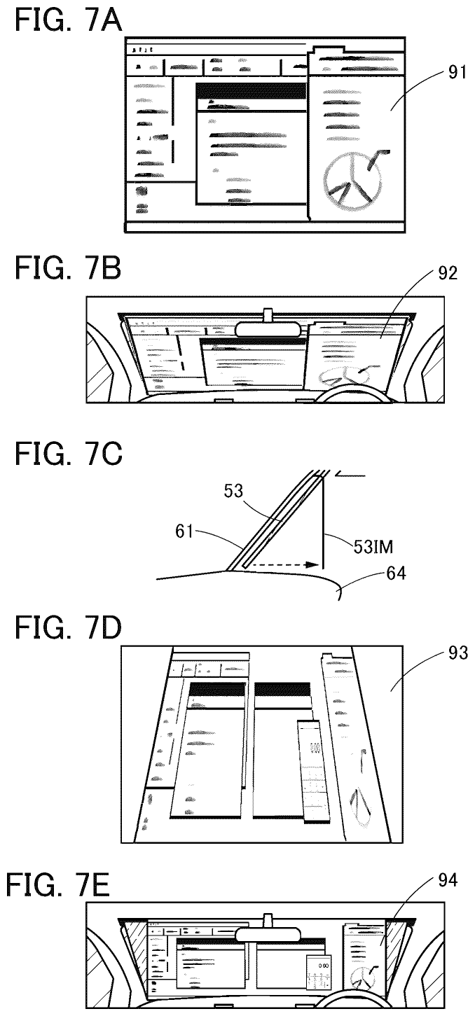

Note that since the display portion 53 included in the light-blocking device 50 is unfolded to approach the windshield 61 of the vehicle body as illustrated in FIG. 1B and the like, the display panel 55 included in the display portion 53 is inclined when seen from a driver's point of view. That is, the upper side of the display panel 55 is located in a position close to the driver's point of view and the lower side of the display panel 55 is located in a position apart from the driver's point of view; therefore, when an image 91 displayed on the display panel 55 (FIG. 7A) is seen from the driver's point of view, the image 91 can be seen as an image 92 in which the vertical width (also referred to as height) of the display panel 55 is narrow and the left-right width (also referred to as breadth) of a lower part of the display panel 55 is narrow (FIG. 7B). Display quality and visibility of an image displayed on the display panel 55 might be impaired when the image is seen in such a way.

Thus, an image processing portion 68 may be included in addition to the structure illustrated in FIG. 3A. FIG. 3B illustrates an example in which the image output portion 67 includes the image processing portion 68. The image processing portion 68 has a function of performing correction processing on image data in order that an image is extended in a vertical direction so that the length in the height direction of the image becomes longer and that the image has a trapezoidal shape where the left-right width of a lower part is wide. FIG. 7C illustrates a conceptual schematic diagram of correction processing performed by the image processing portion 68. The image processing portion 68 preferably has a function of performing correction so that an image displayed on the display portion 53 can be seen as an image positioned in a virtual display position 53IM.

The image output portion 67 in FIG. 3B has a function of outputting an image 93 obtained by correction with the image processing portion 68 (FIG. 7D) to the display panel 55. In that case, an image 94 that is equivalent to the image data before the correction can be visually recognized from the driver's point of view as illustrated in FIG. 7E. Note that although FIG. 3B illustrates the example in which the image output portion 67 includes the image processing portion 68, one embodiment of the present invention is not limited to this structure. The image processing portion 68 may be included separately from the image output portion 67. Note that although FIG. 7A to FIG. 7E schematically illustrate the images displayed on the display panel 55 and the visually recognized images, the difference between the displayed images and the visually recognized images are emphasized more than the actual difference for illustrative purpose.

### Structure Example 2 of Light-Blocking Device

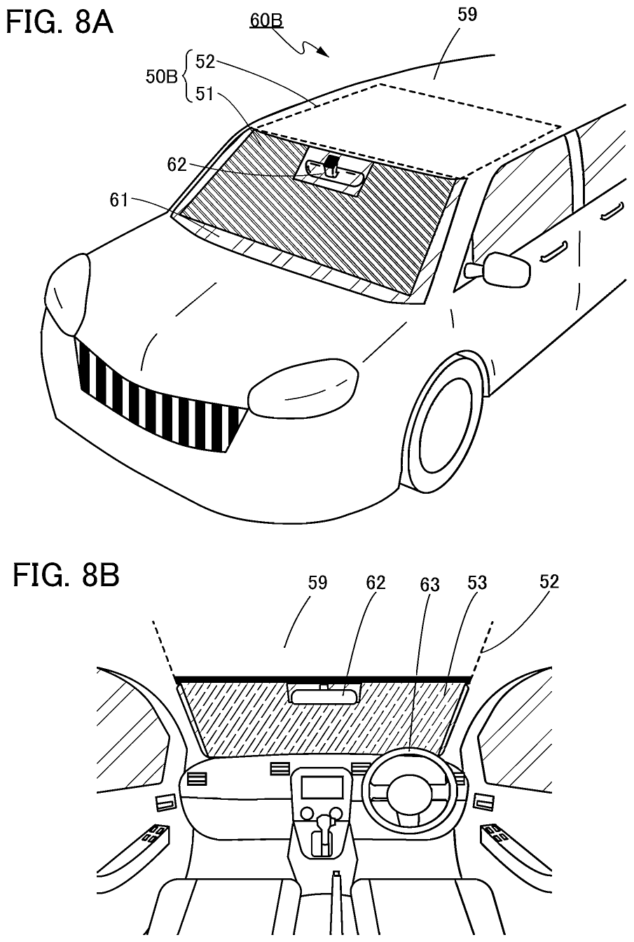

FIG. 8A to FIG. 10D2 illustrate examples of the light-blocking device 50 according to one embodiment of the present invention. Although FIG. 2A and the like each illustrate an example in which the light-blocking device 50 is placed in the vehicle 60A where a rear-view mirror 62 is attached to the roof portion 59, FIG. 8A to FIG. 10D2 each illustrate an example in which a light-blocking device 50B is placed in a vehicle 60B where the rear-view mirror 62 is attached to the windshield 61. FIG. 8A illustrates a schematic bird's eye view of the appearance of the vehicle 60B, and FIG. 8B illustrates a perspective view of the inside of the vehicle 60B. Here, an example is shown in which the light-blocking device 50B including the light-blocking portion 51 that is unfolded near the windshield 61 inside the vehicle 60B is placed in the roof portion 59 of the vehicle 60B.

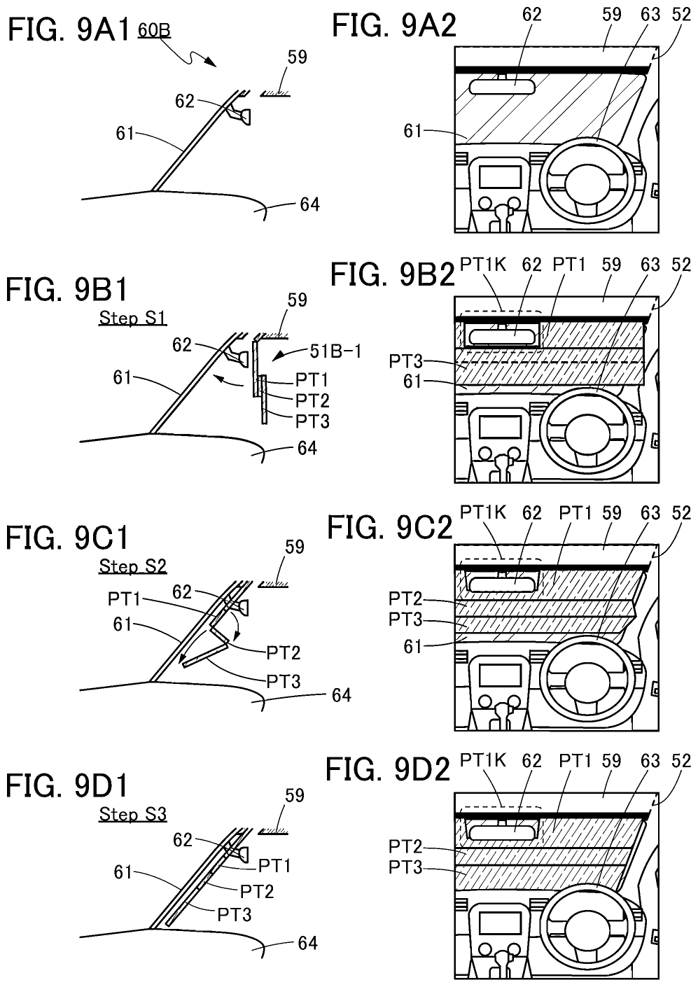

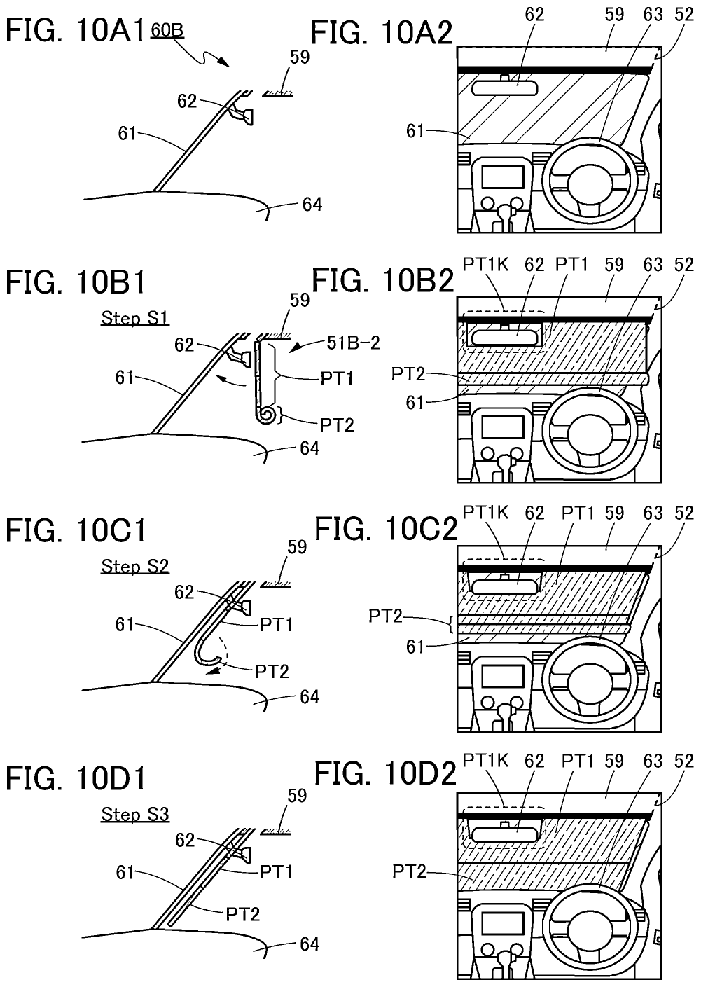

Unlike in the vehicle 60A illustrated in FIG. 1A and the like, in the vehicle 60B illustrated in FIG. 8A and the like, the rear-view mirror 62 is attached to the windshield 61. Therefore, when the light-blocking device 50 is placed in the vehicle 60B and an unfolding operation and a storage operation illustrated in FIG. 2A to FIG. 2C are performed, the light-blocking portion 51 and the rear-view mirror 62 interfere with each other. Accordingly, in the vehicle 60B illustrated in FIG. 8A and the like, the light-blocking device 50B preferably has a function of performing an unfolding operation and a storage operation illustrated in FIG. 9A1 to FIG. 9D2 (Unfolding and Storage Method 1). Alternatively, in the vehicle 60B illustrated in FIG. 8A and the like, the light-blocking device 50B preferably has a function of performing an unfolding operation and a storage operation illustrated in FIG. 10A1 to FIG. 10D2 (Unfolding and Storage Method 2).

### <Unfolding and Storage Method 1 of Light-Blocking Device>

FIG. 9A1 to FIG. 9D2 illustrate an example of the vehicle 60B including a light-blocking device. FIG. 9A1, FIG. 9B1, FIG. 9C1, and FIG. 9D1 are cross-sectional schematic diagrams illustrating the unfolding operation of a light-blocking portion 51B-1. In addition, FIG. 9A2, FIG. 9B2, FIG. 9C2, and FIG. 9D2 illustrate schematic diagrams of the inside of the vehicle corresponding to FIG. 9A1, FIG. 9B1, FIG. 9C1, and FIG. 9D1, respectively.

FIG. 9A1 and FIG. 9A2 show a state in which the light-blocking portion 51B-1 (not illustrated) of a light-blocking device 50B-1 (not illustrated) is stored in the storage portion 52. The light-blocking portion 51B-1 is unfolded in the order of Step S1 shown in FIG. 9B1 and FIG. 9B2, Step S2 shown in FIG. 9C1 and FIG. 9C2, and Step S3 shown in FIG. 9D1 and FIG. 9D2.

As illustrated in FIG. 9B1, the light-blocking portion 51B-1 includes a first portion PT1, a second portion PT2 that is joined to the first portion PT1, and a third portion PT3 that is joined to the second portion PT2. As illustrated in FIG. 9B2 and the like, the first portion PT1 includes an opening portion PT1K in a position overlapping with the rear-view mirror 62. In Step S1 shown in FIG. 9B1, in a state in which there is a region where the first portion PT1, the second portion PT2, and the third portion PT3 overlap with one another, the light-blocking portion 51B-1 is unfolded downwards from the roof portion 59. Next, in Step S2 shown in FIG. 9C1, in a state in which the first portion PT1, the second portion PT2, and the third portion PT3 overlap with one another, the light-blocking portion 51B-1 is inclined to be substantially parallel to (i.e., to approach) the windshield 61 and then the light-blocking portion 51B-1 is unfolded so that the second portion PT2 and the third portion PT3 are substantially parallel to the windshield 61. Accordingly, in Step S3 shown in FIG. 9D1, the light-blocking portion 51B-1 can be unfolded so that the first portion PT1, the second portion PT2, and the third portion PT3 that are included in the light-blocking portion 51B-1 approach the windshield 61. Note that the light-blocking portion 51B-1 can be stored in an order opposite to the above order.

In other words, the light-blocking device 50B-1 has a first mechanism of unfolding the light-blocking portion 51B-1 from the roof portion 59 to the lower part in the state in which there is the region where the first portion PT1, the second portion PT2, and the third portion PT3 overlap with one another. In addition, the light-blocking device 50B-1 has a second mechanism of inclining the light-blocking portion 51B-1 to be substantially parallel to (i.e., to approach) the windshield 61 while the state in which the first portion PT1, the second portion PT2, and the third portion PT3 overlap with one another is kept. Furthermore, the light-blocking device 50B-1 has a third mechanism of unfolding the light-blocking portion 51B-1 so that the second portion PT2 and the third portion PT3 are substantially parallel to the windshield 61 while the first portion PT1 is kept inclined.

By the unfolding method shown in FIG. 9B1 to FIG. 9D1, the light-blocking portion 51B-1 can be unfolded without interference with the rear-view mirror 62 placed in the windshield 61. In addition, by the unfolding method shown in FIG. 9B1 to FIG. 9D1, the light-blocking portion 51B-1 can be unfolded without interference with a dashboard 64 of the vehicle body and a steering wheel 63.

Note that in this specification and the like, “substantially parallel” indicates a state where two straight lines are placed at an angle of greater than or equal to −30° and less than or equal to 30°, for example. Therefore, the case where two straight lines are placed at an angle of greater than or equal to −20° and less than or equal to 200 is also included; the case where two straight lines are placed at an angle of greater than or equal to −10′ and less than or equal to 100 is also included; the case where two straight lines are placed at an angle of greater than or equal to −5° and less than or equal to 5° is also included; and the case where two straight lines are placed at an angle of 0° is also included.

### <Unfolding and Storage Method 2 of Light-Blocking Device>

FIG. 10A1 to FIG. 10D2 illustrate an example of the light-blocking device 50. FIG. 10A1, FIG. 10B1, FIG. 10C1, and FIG. 10D1 are cross-sectional schematic diagrams illustrating the unfolding operation of a light-blocking portion 51B-2 (not illustrated) of a light-blocking device 50B-2 (not illustrated). In addition, FIG. 10A2, FIG. 10B2, FIG. 10C2, and FIG. 10D2 illustrate schematic diagrams of the inside of the vehicle corresponding to FIG. 10A1, FIG. 10B1, FIG. 10C1, and FIG. 10D1, respectively.

FIG. 10A1 and FIG. 10A2 show a state in which the light-blocking portion 51B-2 of the light-blocking device 50B-2 is stored in the storage portion 52. The light-blocking portion 51B-2 is unfolded in the order of Step S1 shown in FIG. 10B1 and FIG. 10B2, Step S2 shown in FIG. 10C1 and FIG. 10C2, and Step S3 shown in FIG. 10D1 and FIG. 10D2.

As illustrated in FIG. 10B1, the light-blocking portion 51B-2 includes the first portion PT1 and the second portion PT2 that is connected to the first portion PT1. As illustrated in FIG. 10B2 and the like, the first portion PT1 includes the opening portion PT1K in a position overlapping with the rear-view mirror 62. In Step S1 shown in FIG. 10B1, in a state in which the second portion PT2 is rounded, the first portion PT1 is unfolded downwards from the roof portion 59. Next, in Step S2 shown in FIG. 9C1, the light-blocking portion 51B-2 is inclined to approach the windshield 61 while the second portion PT2 is kept rounded, and then the second portion PT2 is unfolded toward the lower end of the windshield 61. Accordingly, in Step S3 shown in FIG. 10D1, the light-blocking portion 51B-2 can be unfolded so that the first portion PT1 and the second portion PT2 that are included in the light-blocking portion 51B-2 approach the windshield 61. Note that the light-blocking portion 51B-2 can be stored in an order opposite to the above order.

By the unfolding method shown in FIG. 10B1 to FIG. 10D1, the light-blocking portion 51B-2 can be unfolded without interference with the rear-view mirror 62 placed in the windshield 61. In addition, by the unfolding method shown in FIG. 10B1 to FIG. 10D1, the light-blocking portion 51B-2 can be unfolded without interference with the dashboard 64 and steering wheel 63. Note that the light-blocking portion 51B-2 can be stored in the order opposite to the above order.

Note that the light-blocking device 50B-1 and the light-blocking device 50B-2 described in Structure Example 2 of Light-Blocking Device can each have the same structure as the light-blocking device 50 described in Structure Example 1 of Light-Blocking Device except that their unfolding and storage methods are different.

### Structure Example 3 of Light-Blocking Device

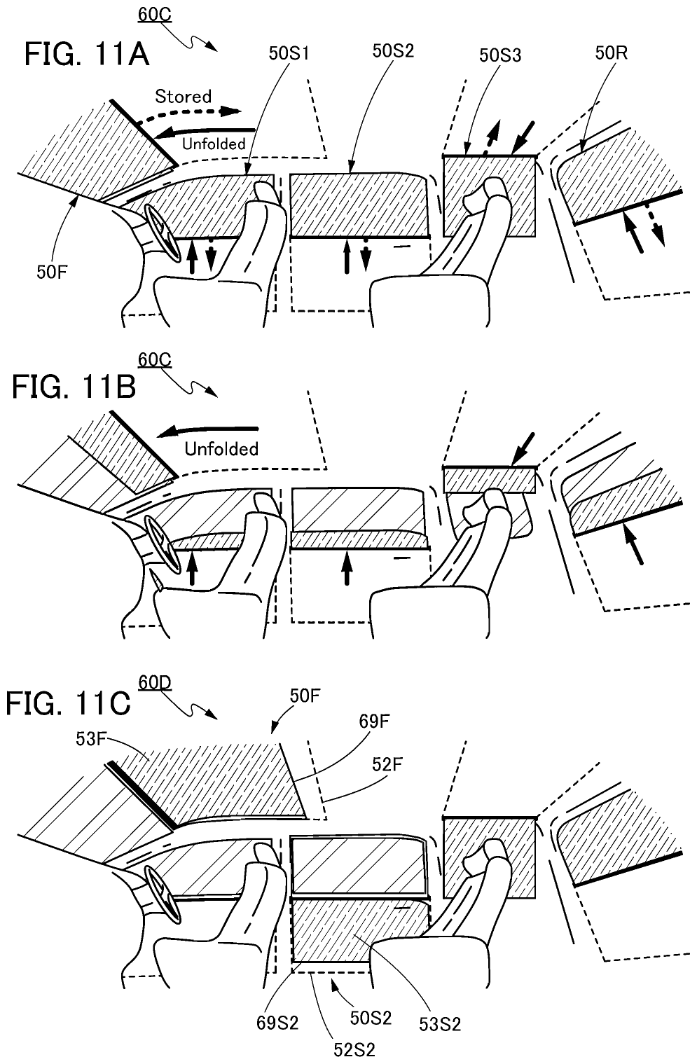

Structure Example 1 of Light-Blocking Device and Structure Example 2 of Light-Blocking Device show the examples in which the light-blocking devices (50, 50B, 50B-1, and 50B-2) are provided in the vehicles 60 (the vehicle 60A and the vehicle 60B) on the windshield 61 side; however, one embodiment of the present invention is not limited to the case where the light-blocking devices are placed on the windshield 61 side. The light-blocking devices may be provided on the side window side and rear window side of the vehicles. Perspective views of the insides of a vehicle 60C and a vehicle 60D in FIG. 11A to FIG. 11C show examples in which the light-blocking devices are provided on the windshield side (50F), the side window sides (50S1, 50S2, and 50S), and the rear window side (50R). FIG. 11B is a diagram showing a state during the unfolding operations of the light-blocking devices 50F, 50S1, 50S2, 50S3, and 50R. FIG. 11C is a diagram showing a modification example of the vehicle 60 including the light-blocking device 50. Although the positions where the light-blocking device 50S1, the light-blocking device 50S2, the light-blocking device 50S3, and the light-blocking device 50R illustrated in FIG. 11A to FIG. 11C are placed in the vehicles are different, the structures of the light-blocking devices (50, 50B, 50B-1, and 50B-2) described in Structure Example 1 of Light-Blocking Device or Structure Example 2 of Light-Blocking Device can be used.

Also in the case where transmitting portions 69 (69F and 69S2) are provided in storage portions 52F and 52S2 of the light-blocking devices 50F and 50S2 and the light-blocking portion 51 is stored as illustrated in FIG. 11C (for example, in the case where the light-blocking portion 51 is placed in the position shown in FIG. 2A), when display portions 53F and 53S2 included in the light-blocking portion 51 overlap with the transmitting portions 69F and 69S2, display on the display portions 53F and 53S2 may be seen from the inside of the vehicle. For example, in the case where the storage portion 52F included in the light-blocking device 50F includes the transmitting portion 69F, when the display portion 53F displays an image (video taken by an imaging means that is not illustrated) of the upper part of the vehicle 60D, the light-blocking device 50F can improve the beauty of the vehicle 60D as a substitute for a sun roof. The light-blocking device 50F is preferably used as a substitute for a sun roof because it is lighter than a common sun roof made of glass.

Note that although a vehicle is given above as an example of a moving object in this embodiment, the moving object is not limited to a vehicle. Examples of moving objects include a train, a monorail train, a ship, and a flying object (a helicopter, an airplane, and a rocket). In addition, examples of vehicles include a motor vehicle, a bus, and a truck.

At least part of this embodiment can be implemented in appropriate combination with the other embodiments described in this specification.

### Embodiment 2

In this embodiment, structure examples of a display device that can be used as the light-blocking device according to one embodiment of the present invention are described. A display device described below as an example can be employed for the display panel 55 in Embodiment 1.

One embodiment of the present invention is a display device including a light-emitting element (also referred to as a light-emitting device). The display device includes two or more light-emitting elements that emit light of different colors. The light-emitting elements each include a pair of electrodes and an EL layer therebetween. The light-emitting elements are preferably organic EL elements (organic electroluminescent elements). The two or more light-emitting elements that exhibit different colors include EL layers containing different light-emitting materials. For example, when three kinds of light-emitting elements that emit red (R), green (G), and blue (B) light are included, a full-color display device can be achieved.

In the case of manufacturing a display device including a plurality of light-emitting elements that emit light of different emission colors, layers (light-emitting layers) containing at least light-emitting materials of different emission colors each need to be formed in an island shape. In the case of separately forming some or all of EL layers, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a deposited film due to vapor scattering, for example; accordingly, it is difficult to achieve high definition and a high aperture ratio. In addition, the outline of the layer might blur during evaporation, so that the thickness of an end portion might be reduced. That is, the thickness of an island-shaped light-emitting layer might vary from place to place. In addition, in the case of manufacturing a display device with a large size, high resolution, or high definition, a manufacturing yield might be reduced because of low dimensional accuracy of the metal mask and deformation due to heat or the like. Thus, a measure has been taken for a pseudo increase in definition (also referred to as pixel density) by employing a unique pixel arrangement such as a PenTile arrangement.

Note that in this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by photolithography without using a shadow mask such as a fine metal mask (an FMM). Accordingly, it is possible to achieve a display device with high definition and a high aperture ratio, which has been difficult to achieve. Moreover, since the EL layers can be formed separately, it is possible to achieve a display device that performs extremely clear display with high contrast and high display quality. Note that, fine patterning of the EL layers may be performed using both a metal mask and photolithography, for example.

In addition, some or all of the EL layers can be physically divided from each other. This can inhibit leakage current flowing between adjacent light-emitting elements through a layer (also referred to as a common layer) shared by the light-emitting elements. Thus, it is possible to prevent crosstalk due to unintended light emission, so that a display device with extremely high contrast can be achieved. In particular, a display device having high current efficiency at low luminance can be achieved.

Note that in one embodiment of the present invention, the display device can be also obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, some or all of the EL layers are divided from each other by photolithography. Thus, leakage current through the common layer is suppressed; accordingly, a high-contrast display device can be achieved. In particular, when an element has a tandem structure in which a plurality of light-emitting layers are stacked with a highly conductive intermediate layer therebetween, leakage current through the intermediate layer can be effectively prevented, so that a display device with high luminance, high definition, and high contrast can be achieved.

Furthermore, an insulating layer covering at least a side surface of the island-shaped light-emitting layer is preferably provided. The insulating layer may cover part of a top surface of an island-shaped EL layer. For the insulating layer, a material having a barrier property against water and oxygen is preferably used. For example, an inorganic insulating film that is less likely to diffuse water or oxygen can be used. This can inhibit degradation of the EL layer and can achieve a highly reliable display device.

Moreover, between two adjacent light-emitting elements, there is a region (concave portion) where none of the EL layers of the light-emitting elements is provided. In the case where a common electrode or a common electrode and a common layer are formed to cover the concave portion, a phenomenon where the common electrode is divided by a step at an end portion of the EL layer (such a phenomenon is also referred to as disconnection) might occur, which might cause insulation of the common electrode over the EL layer. In view of this, a local gap between the two adjacent light-emitting elements is preferably filled with a resin layer (also referred to as local filling planarization, or LFP) functioning as a planarization film. The resin layer has a function of a planarization film. This structure can inhibit disconnection of the common layer or the common electrode and can achieve a highly reliable display device.

More specific structure examples of the display device according to one embodiment of the present invention will be described below with reference to drawings.

### Structure Example 1

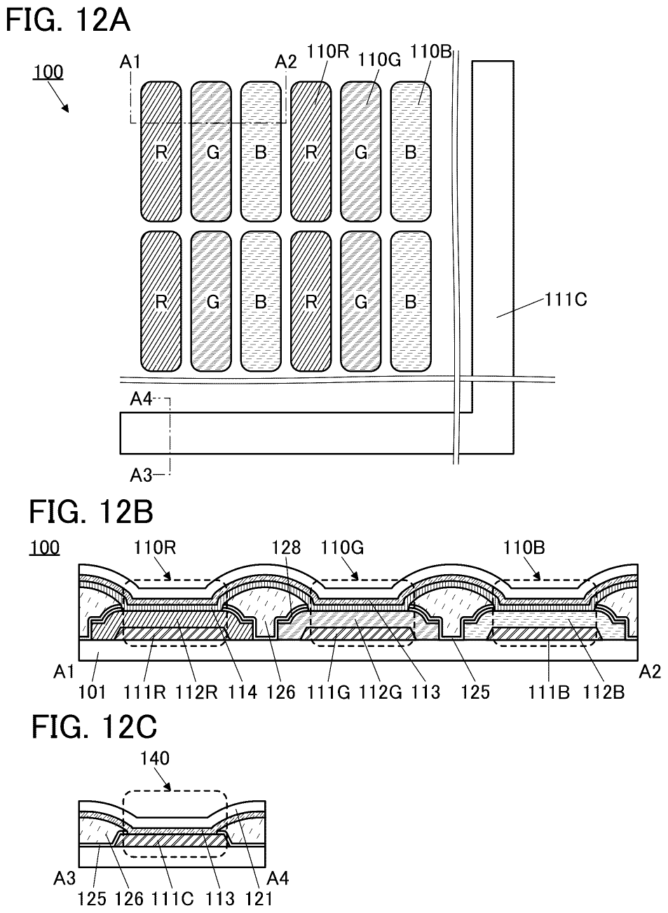

FIG. 12A illustrates a schematic top view of a display device 100 according to one embodiment of the present invention. The display device 100 includes, over a substrate 101, a plurality of light-emitting elements 110R exhibiting red, a plurality of light-emitting elements 110G exhibiting green, and a plurality of light-emitting elements 110B exhibiting blue. In FIG. 12A, light-emitting regions of the light-emitting elements are denoted by R, G, and B to easily differentiate the light-emitting elements.

The light-emitting elements 110R, the light-emitting elements 110G, and the light-emitting elements 110B are each arranged in a matrix. FIG. 12A illustrates what is called a stripe arrangement, in which the light-emitting elements of the same color are arranged in one direction. Note that an arrangement method of the light-emitting elements is not limited thereto; an arrangement method such as an S-stripe arrangement, a delta arrangement, a Bayer arrangement, or a zigzag arrangement may be employed, or a PenTile arrangement, a diamond arrangement, or the like can be also used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As a light-emitting substance contained in the EL element, a substance that emits fluorescent light (a fluorescent material), a substance that emits phosphorescent light (a phosphorescent material), an inorganic compound (e.g., a quantum dot material), and a substance that exhibits thermally activated delayed fluorescence (a thermally activated delayed fluorescent (TADF) material) can be given, for example.

FIG. 12A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or the connection electrode 111C may be provided along two or more sides of the outer periphery of the display region. That is, in the case where the display region has a rectangular top surface shape, a top surface shape of the connection electrode 111C can have a band shape (a rectangle), an L shape, a U shape (a square bracket shape), a quadrangular shape, or the like.

FIG. 12B and FIG. 12C are schematic cross-sectional views corresponding to the dashed dotted line A1-A2 and the dashed dotted line A3-A4 in FIG. 12A. FIG. 12B illustrates a schematic cross-sectional view of the light-emitting element 110R, the light-emitting element 110G, and the light-emitting element 110B, and FIG. 12C illustrates a schematic cross-sectional view of a connection portion 140 where the connection electrode 111C and the common electrode 113 are connected to each other.

The light-emitting element 11 OR includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits light with intensity in a red wavelength range. The organic layer 112G included in the light-emitting element 110G contains at least a light-emitting organic compound that emits light with intensity in a green wavelength range. The organic layer 112B included in the light-emitting element 110B contains at least a light-emitting organic compound that emits light with intensity in a blue wavelength range. Each of the organic layer 112R, the organic layer 112G, and the organic layer 112B can be also referred to as an EL layer and includes at least a layer containing a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 includes a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have light-transmitting properties and the common electrode 113 has a reflective property, a bottom-emission display device can be obtained. In contrast, when the pixel electrodes have reflective properties and the common electrode 113 has a light-transmitting property, atop-emission display device can be obtained. Note that when both the pixel electrodes and the common electrode 113 have light-transmitting properties, a dual-emission display device can be also obtained.

A protective layer 121 is provided over the common electrode 113 to cover the light-emitting element 110R, the light-emitting element 110G, and the light-emitting element 110n. The protective layer 121 has a function of preventing diffusion of impurities such as water into each light-emitting element from the above.

End portions of the pixel electrodes 111 (111R, 111G, and 1111B) preferably have a tapered shape. In the case where the end portions of the pixel electrodes have a tapered shape, the organic layers 112 that are provided along side surfaces of the pixel electrodes also have a tapered shape. When the side surfaces of the pixel electrodes have a tapered shape, coverage with the EL layers provided along the side surfaces of the pixel electrodes can be improved. Furthermore, when the side surfaces of the pixel electrodes have a tapered shape, a material (for example, also referred to as dust or particles) in a manufacturing step is easily removed by processing such as cleaning, which is preferable.

Note that in this specification and the like, a tapered shape indicates a shape in which at least part of a side surface of a structure is inclined to a substrate surface. For example, a tapered shape preferably includes a region where an angle formed between the inclined side surface and the substrate surface (such an angle is also referred to as a taper angle) is less than 90°.

The organic layer 112 is processed into an island shape by a photolithography method. Thus, an angle formed between a top surface and a side surface of an end portion of the organic layer 112 is approximately 90°. In contrast, an organic film formed using an FMM (Fine Metal Mask) or the like has a thickness that tends to gradually decrease with decreasing the distance from an end portion, and has a top surface forming a slope in an area extending greater than or equal to 1 m and less than or equal to 10 m from the end portion, for example. Thus, such an organic film has a shape whose top surface and side surface are difficult to distinguish from each other.

An insulating layer 125, a resin layer 126, and a layer 128 are included between two adjacent light-emitting elements.

Between two adjacent light-emitting elements, side surfaces of the organic layers 112 are provided to face each other with the resin layer 126 therebetween. The resin layer 126 is positioned between the two adjacent light-emitting elements and is provided to fill end portions of the organic layers 112 and a region between the two organic layers 112. The resin layer 126 has a top surface with a smooth convex shape. The common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode over the organic layer 112 from being insulated. The resin layer 126 can be also referred to as LFP (Local Filling Planarization).

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive photosensitive material or a negative photosensitive material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surfaces of the organic layers 112. In addition, the insulating layer 125 is provided to cover an upper end portion of the organic layer 112. Furthermore, part of the insulating layer 125 is provided in contact with a top surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved by an organic solvent or the like used at the time of forming the resin layer 126. Therefore, the insulating layer 125 is provided between the organic layer 112 and the resin layer 126 as described in this embodiment to protect the side surfaces of the organic layer.

An insulating layer containing an organic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

For the formation of the insulating layer 125, a sputtering method, a CVD method, a PLD method, an ALD method, or the like can be used. The insulating layer 125 is preferably formed by an ALD method achieving good coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 is provided to cover the common electrode 113.

The protective layer 121 can have, for example, a single-layer structure or a stacked-layer structure including at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. Moreover, the top surface of the protective layer 121 is flat; therefore, when a structural object (e.g., a color filter, an electrode of a touch sensor, a lens array, or the like) is provided above the protective layer 121, the structural object can be less affected by an uneven shape caused by a lower structure.

FIG. 12C illustrates the connection portion 140 in which the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 12C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin. Thus, problems do not arise in many cases even when the common layer 114 is positioned in the connection portion 140. Accordingly, the common electrode 113 and the common layer 114 can be formed using the same shielding mask, so that manufacturing cost can be reduced.

The above is the description of the structure example of the display device.

### [Pixel Layout]

Pixel layout different from that in FIG. 12A will be mainly described below. There is no particular limitation on the arrangement of light-emitting elements (subpixels), and a variety of methods can be employed.

In addition, examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to a top surface shape of a light-emitting region of the light-emitting element.

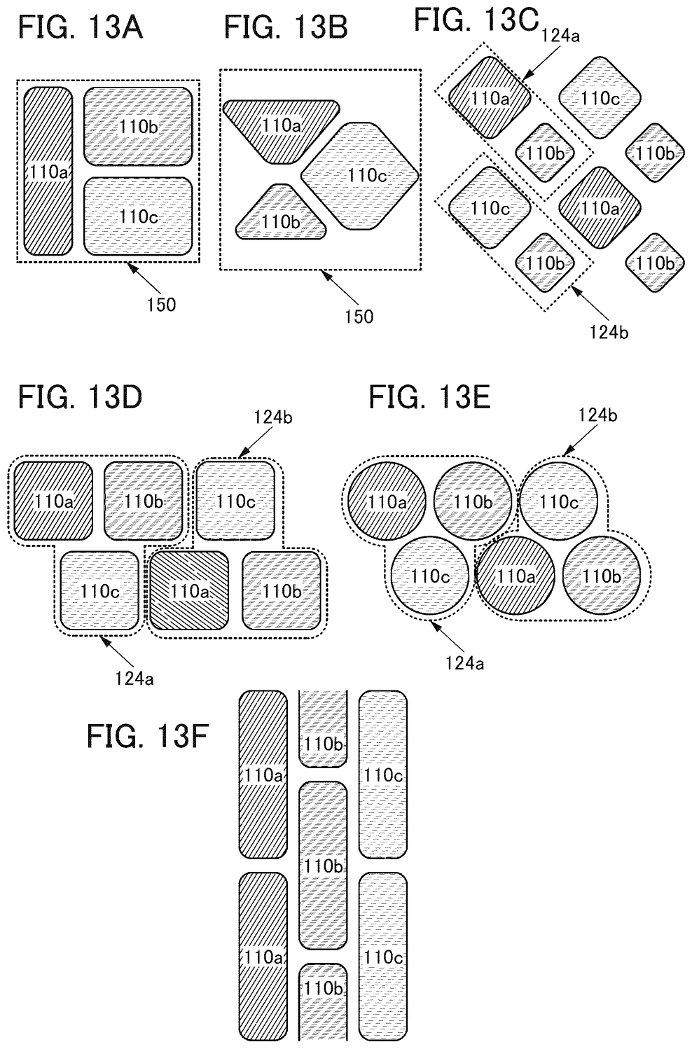

A pixel 150 illustrated in FIG. 13A employs an S-stripe arrangement. The pixel 150 illustrated in FIG. 13A is composed of three subpixels: light-emitting elements 110a, 110b, and 110c. For example, the light-emitting element 110a may be a blue-light-emitting element, the light-emitting element 110b may be a red-light-emitting element, and the light-emitting element 110c may be a green-light-emitting element.

The pixel 150 illustrated in FIG. 13B includes the light-emitting element 110a whose top surface has a rough trapezoidal shape with rounded corners, the light-emitting element 110b whose top surface has a rough triangle shape with rounded corners, and the light-emitting element 110c whose top surface has a rough tetragonal or rough hexagonal shape with rounded corners. In addition, the light-emitting element 110a has a larger light-emitting area than the light-emitting element 110b. In this manner, the shapes and sizes of the light-emitting elements can be determined independently. For example, the size of a light-emitting element with higher reliability can be made smaller. For example, the light-emitting element 110a may be a green light-emitting element, the light-emitting element 110b may be a red light-emitting element, and the light-emitting element 110c may be a blue light-emitting element.

Pixels 124a and 124b illustrated in FIG. 13C employ a PenTile arrangement. FIG. 13C illustrates an example in which the pixels 124a each including the light-emitting element 110a and the light-emitting element 110b and the pixels 124b each including the light-emitting element 110b and the light-emitting element 110c are alternately arranged. For example, the light-emitting element 110a may be a red light-emitting element, the light-emitting element 110b may be a green light-emitting element, and the light-emitting element 110c may be a blue light-emitting element.

The pixels 124a and 124b illustrated in FIG. 13D and FIG. 13E employ a delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red light-emitting element, the light-emitting element 110b may be a green light-emitting element, and the light-emitting element 110c may be a blue light-emitting element.

FIG. 13D illustrates an example in which the top surface of each light-emitting element has a rough tetragonal shape with rounded corners, and FIG. 13E illustrates an example in which the top surface of each light-emitting element is circular.

FIG. 13F illustrates an example in which light-emitting elements of different colors are arranged in a zigzag manner. Specifically, the positions of top sides of two light-emitting elements arranged in a column direction (e.g., the light-emitting element 110a and the light-emitting element 110b or the light-emitting element 110b and the light-emitting element 110c) are not aligned in a top view. For example, the light-emitting element 110a may be a red light-emitting element, the light-emitting element 110b may be a green light-emitting element, and the light-emitting element 110c may be a blue light-emitting element.

In a photolithography method, as a pattern to be processed becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a light-emitting element has a polygonal shape with rounded corners, an elliptical shape, a circular shape, or the like in some cases.

Furthermore, in a method for manufacturing a display panel according to one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of a resist material. An insufficiently cured resist film might have a shape different from a desired shape at the time of processing. As a result, a top surface of the EL layer has a polygonal shape with rounded corners, an elliptical shape, a circular shape, or the like in some cases. For example, when a resist mask with a square top surface is intended to be formed, a resist mask with a circular top surface might be formed, and the top surface of the EL layer might be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

At least part of this embodiment can be implemented in appropriate combination with the other embodiments described in this specification.

### Embodiment 3

In this embodiment, structure examples of the display device according to one embodiment of the present invention will be described.

The display device of this embodiment can be used for, for example, display portions of a digital camera, a digital video camera, a digital photo frame, a cellular phone, a portable game machine, a smartphone, a wristwatch-type terminal, a tablet terminal, a portable information terminal, and an audio reproducing device, in addition to electronic devices with comparatively large screens, such as a television device, a desktop or laptop personal computer, a monitor for a computer or the like, digital signage, and a large game machine such as a pachinko machine.

### [Display Device 400]

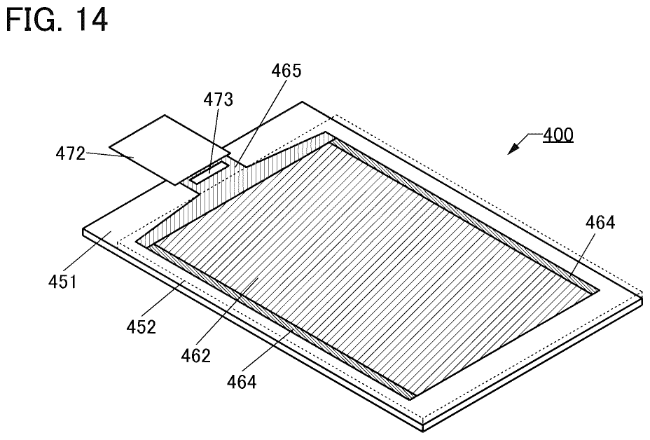

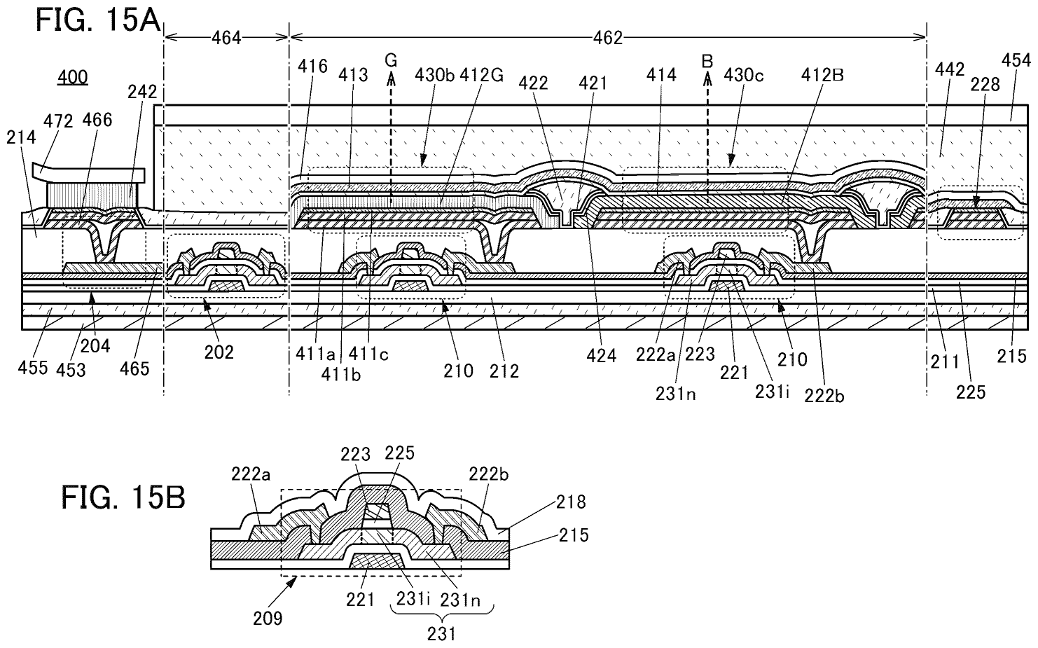

FIG. 14 is a perspective view of a display device 400, and FIG. 15A is a cross-sectional view of the display device 400.

The display device 400 has a structure in which a substrate 452 and a substrate 451 are attached to each other. In FIG. 14, the substrate 452 is denoted by a broken line.

The display device 400 includes a display portion 462, a circuit 464, a wiring 465, and the like. FIG. 14 illustrates an example in which an IC 473 and an FPC 472 are implemented on the display device 400. Thus, the structure illustrated in FIG. 14 can be regarded as a display module including the display device 400, the IC (integrated circuit), and the FPC.

As the circuit 464, a scan line driver circuit can be used, for example.

The wiring 465 has a function of supplying a signal and power to the display portion 462 and the circuit 464. The signal and power are input to the wiring 465 from the outside through the FPC 472 or input to the wiring 465 from the IC 473.

FIG. 14 illustrates an example in which the IC 473 is provided over the substrate 451 by a COG (Chip On Glass) method, a COF (Chip on Film) method, or the like. An IC including a scan line driver circuit, a signal line driver circuit, or the like can be employed as the IC 473, for example. Note that the display device 400 and the display module are not necessarily provided with an IC. In addition, the IC may be implemented on the FPC by a COF method or the like.

FIG. 15A illustrates an example of a cross section of the display device 400 when part of a region including the FPC 472, part of the circuit 464, part of the display portion 462, and part of a region including a connection portion are cut. FIG. 15A particularly illustrates an example of a cross section of the display portion 462 when a region including a light-emitting element 430b that emits green light and a light-emitting element 430c that emits blue light is cut.

The display device 400 illustrated in FIG. 15A includes a transistor 202, transistors 210, the light-emitting element 430b, the light-emitting element 430c, and the like between a substrate 453 and a substrate 454.

The light-emitting element illustrated in Embodiment 2 can be employed as the light-emitting element 430b and the light-emitting element 430c.

Here, in the case where a pixel of the display device includes three kinds of subpixels that exhibit different colors, subpixels of three colors of red (R), green (G), and blue (B), subpixels of three colors of yellow (Y), cyan (C), and magenta (M), and the like can be given as the three subpixels. In the case where the pixel includes four subpixels, subpixels of four colors of R, G, B, and white (W), subpixels of four colors of R, G, B, and Y, and the like can be given as the four subpixels.

The substrate 454 and a protective layer 416 are bonded to each other with an adhesive layer 442. The adhesive layer 442 is provided to overlap with the light-emitting element 430b and the light-emitting element 430c, and the display device 400 employs a solid sealing structure.

The light-emitting element 430b and the light-emitting element 430c each include a conductive layer 411a, a conductive layer 411b, and a conductive layer 411c as a pixel electrode. The conductive layer 411b has a property of reflecting visible light and functions as a reflective electrode. The conductive layer 411c has a property of transmitting visible light and functions as an optical adjustment layer.

The conductive layer 411a is connected to a conductive layer 222b included in the transistor 210 through an opening provided in an insulating layer 214. The transistor 210 has a function of controlling driving of the light-emitting element.

An EL layer 412G or an EL layer 412B is provided to cover the pixel electrode. An insulating layer 421 is provided in contact with a side surface of the EL layer 412G and a side surface of the EL layer 412B, and a resin layer 422 is provided to fill a concave portion of the insulating layer 421. A layer 424 is provided between the EL layer 412G and the insulating layer 421 and between the EL layer 412B and the insulating layer 421. A common layer 414, a common electrode 413, and the protective layer 416 are provided to cover the EL layer 412G and the EL layer 412B.

Light emitted from the light-emitting element is emitted toward the substrate 452 side. For the substrate 452, a material having a high property of transmitting visible light is preferably used.

The transistor 202 and the transistor 210 can be manufactured using the same material in the same step.

The substrate 453 and an insulating layer 212 are attached to each other with an adhesive layer 455.

As a method for manufacturing the display device 400, first, a manufacture substrate provided with the insulating layer 212, the transistors, the light-emitting elements, and the like is attached to the substrate 454 with the adhesive layer 442. Then, the substrate 453 is attached to a surface exposed by separation of the manufacture substrate, so that the components formed over the manufacture substrate are transferred to the substrate 453. The substrate 453 and the substrate 454 each preferably have flexibility. This can increase the flexibility of the display device 400.

An inorganic insulating film that can be used for each of an insulating layer 211 and an insulating layer 215 can be used for the insulating layer 212.

A connection portion 204 is provided in a region of the substrate 453 where the substrate 453 and the substrate 454 do not overlap with each other. In the connection portion 204, the wiring 465 is electrically connected to the FPC 472 through a conductive layer 466 and a connection layer 242. The conductive layer 466 can be obtained by processing the same conductive film as the pixel electrode. Thus, the connection portion 204 and the FPC 472 can be electrically connected to each other through the connection layer 242.

Each of the transistor 202 and the transistor 210 includes a conductive layer 221 functioning as a gate, the insulating layer 211 functioning as a gate insulating layer, a semiconductor layer including a channel formation region 231i and a pair of low-resistance regions 231n, a conductive layer 222a connected to one of the pair of low-resistance regions 231n, the conductive layer 222b connected to the other of the pair of low-resistance regions 231n, an insulating layer 225 functioning as a gate insulating layer, a conductive layer 223 functioning as a gate, and the insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the low-resistance regions 231n through openings provided in the insulating layer 215. One of the conductive layer 222a and the conductive layer 222b functions as a source, and the other of the conductive layer 222a and the conductive layer 222b functions as a drain.

FIG. 15A illustrates an example in which the insulating layer 225 covers a top surface and side surfaces of the semiconductor layer. The conductive layer 222a and the conductive layer 222b are connected to the low-resistance regions 231n through openings provided in the insulating layer 225 and the insulating layer 215.

In contrast, in a transistor 209 illustrated in FIG. 15B, the insulating layer 225 overlaps with the channel formation region 231i of the semiconductor layer 231 and does not overlap with the low-resistance regions 231n. The structure illustrated in FIG. 15B can be manufactured by processing the insulating layer 225 with the conductive layer 223 as a mask, for example. In FIG. 15B, the insulating layer 215 is provided to cover the insulating layer 225 and the conductive layer 223, and the conductive layer 222a and the conductive layer 222b are connected to the low-resistance regions 231n through openings in the insulating layer 215. Furthermore, an insulating layer 218 covering the transistor may be provided.

There is no particular limitation on the structure of the transistors included in the display device of this embodiment. For example, a planar transistor, a staggered transistor, an inverted staggered transistor, or the like can be used. In addition, either of a top-gate transistor structure and a bottom-gate transistor structure may be employed. Alternatively, gates may be provided above and below a semiconductor layer where a channel is formed.

The structure in which the semiconductor layer where a channel is formed is sandwiched between two gates is employed for the transistor 202 and the transistor 210. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity because degradation of transistor characteristics can be inhibited.

The semiconductor layer of the transistor preferably contains a metal oxide (also referred to as an oxide semiconductor). That is, a transistor using a metal oxide in its channel formation region (hereinafter, an OS transistor) is preferably used for the display device of this embodiment.

The band gap of a metal oxide used for the semiconductor layer of the transistor is preferably greater than or equal to 2 eV, further preferably greater than or equal to 2.5 eV. With the use of a metal oxide having a wide bandgap, the off-state current of the OS transistor can be reduced.

A metal oxide preferably contains at least indium or zinc, and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may contain silicon. Examples of silicon include amorphous silicon and crystalline silicon (low-temperature polysilicon, single crystal silicon, or the like).

The transistor included in the circuit 464 and the transistor included in the display portion 462 may have either the same structure or different structures. A plurality of transistors included in the circuit 464 may have either the same structure or two or more kinds of structures. Similarly, a plurality of transistors included in the display portion 462 may have either the same structure or two or more kinds of structures.

A material through which impurities such as water and hydrogen do not easily diffuse is preferably used for at least one of the insulating layers covering the transistors. Thus, such an insulating layer can function as a barrier layer. Such a structure can effectively inhibit diffusion of impurities into the transistors from the outside and can increase the reliability of the display device.

An inorganic insulating film is preferably used for each of the insulating layer 211, the insulating layer 212, the insulating layer 215, the insulating layer 218, and the insulating layer 225. As the inorganic insulating film, a silicon nitride film, a silicon oxynitride film, a silicon oxide film, a silicon nitride oxide film, an aluminum oxide film, an aluminum nitride film, or the like can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above inorganic insulating films may also be used.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

A variety of optical members can be arranged on the inner or outer surface of the substrate 454. Examples of the optical members include a light-blocking layer, a polarizing plate, a retardation plate, a light diffusion layer (a diffusion film or the like), an anti-reflection layer, a microlens array, and a light-condensing film. Furthermore, an antistatic film inhibiting attachment of dust, a water repellent film suppressing attachment of stain, a hard coat film inhibiting generation of a scratch caused by the use, a shock absorbing layer, or the like may be provided on the outside of the substrate 454.

Providing the protective layer 416 that covers the light-emitting element can inhibit entry of impurities such as water into the light-emitting element, so that the reliability of the light-emitting element can be increased.

FIG. 15A illustrates a connection portion 228. In the connection portion 228, the common electrode 413 is electrically connected to a wiring. FIG. 15A illustrates an example in which the wiring has the same stacked-layer structure as the pixel electrode.

For each of the substrate 453 and the substrate 454, glass, quartz, ceramic, sapphire, a resin, a metal, an alloy, a semiconductor, or the like can be used. For the substrate on the side from which light from the light-emitting element is extracted, a material that transmits the light is used. When a flexible material is used for the substrate 453 and the substrate 454, the flexibility of the display device can be increased. Furthermore, a polarizing plate may be used as the substrate 453 or the substrate 454.

For each of the substrate 453 and the substrate 454, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (nylon, aramid, or the like), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used for one or both of the substrate 453 and the substrate 454.

For the adhesive layer, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. Alternatively, an adhesive sheet or the like may be used.

As the connection layer 242, an anisotropic conductive film (ACF), an anisotropic conductive paste (ACP), or the like can be used.

As materials that can be used for conductive layers such as a variety of wirings and electrodes that constitute the display device, in addition to a gate, a source, and a drain of a transistor, a metal such as aluminum, titanium, chromium, nickel, copper, yttrium, zirconium, molybdenum, silver, tantalum, or tungsten, an alloy containing the metal as its main component, and the like can be given. A film containing these materials can be used in a single layer or as a stacked-layer structure.

In addition, as a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the material is made thin enough to have a light-transmitting property. Furthermore, a stacked-layer film of the above materials can be used for a conductive layer. For example, a stacked-layer film of indium tin oxide and an alloy of silver and magnesium, or the like is preferably used because conductivity can be increased. They can be also used for conductive layers such as a variety of wirings and electrodes that constitute the display device, and conductive layers (conductive layers functioning as a pixel electrode or a common electrode) included in the light-emitting element.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

At least part of this embodiment can be implemented in appropriate combination with the other embodiments described in this specification.

### Embodiment 4

In this embodiment, a light-emitting element (also referred to as a light-emitting device) that can be used in the display device according to one embodiment of the present invention will be described.

In this specification and the like, a device manufactured using a metal mask or an FMM (a fine metal mask or a high-definition metal mask) is sometimes referred to as a device having an MM (metal mask) structure. In addition, in this specification and the like, a device manufactured without using a metal mask or an FMM is sometimes referred to as a device having an MML (metal maskless) structure.

Note that in this specification and the like, a structure where light-emitting layers in light-emitting devices of different colors (here, blue (B), green (G), and red (R)) are separately formed or separately patterned is sometimes referred to as an SBS (Side By Side) structure. In addition, in this specification and the like, a light-emitting device capable of emitting white light is sometimes referred to as a white-light-emitting device. Note that a combination of white-light-emitting devices with coloring layers (e.g., color filters) enables a full-color display device.

### [Light-Emitting Device]

Structures of light-emitting devices can be classified roughly into a single structure and a tandem structure. A light-emitting device having a single structure includes one light-emitting unit between a pair of electrodes. The light-emitting unit includes one or more light-emitting layers. To obtain white light emission with a single structure, two light-emitting layers are selected so that light emission of the light-emitting layers has a relationship of complementary colors. For example, when the emission color of a first light-emitting layer and the emission color of a second light-emitting layer have a relationship of complementary colors, it is possible to obtain a structure where the light-emitting device emits white light as a whole. Furthermore, in the case of a light-emitting device including three or more light-emitting layers, the light-emitting device is configured to be able to emit white light as a whole by combining the emission colors of the three or more light-emitting layers.

A light-emitting device having a tandem structure includes a plurality of light-emitting units between a pair of electrodes, and each light-emitting unit includes one or more light-emitting layers. When light-emitting layers that emit light of the same color are used in each light-emitting unit, luminance per predetermined current can be increased, and the light-emitting device can have higher reliability than that with a single structure. To obtain white light emission with a tandem structure, the structure is made so that light from light-emitting layers of the plurality of light-emitting units can be combined to be white light. Note that a combination of emission colors for obtaining white light emission is similar to that in the case of a single structure. Note that in the device having a tandem structure, it is suitable to provide an intermediate layer such as a charge-generation layer between a plurality of light-emitting units.

When a white light-emitting device and a light-emitting device having an SBS structure are compared with each other, the light-emitting device having the SBS structure can have lower power consumption than the white light-emitting device. Meanwhile, the white-light-emitting device can achieve lower manufacturing cost and a higher manufacturing yield because the manufacturing process of the white-light-emitting device is simpler than that of the light-emitting device having the SBS structure.

### Structure Example of Light-Emitting Device

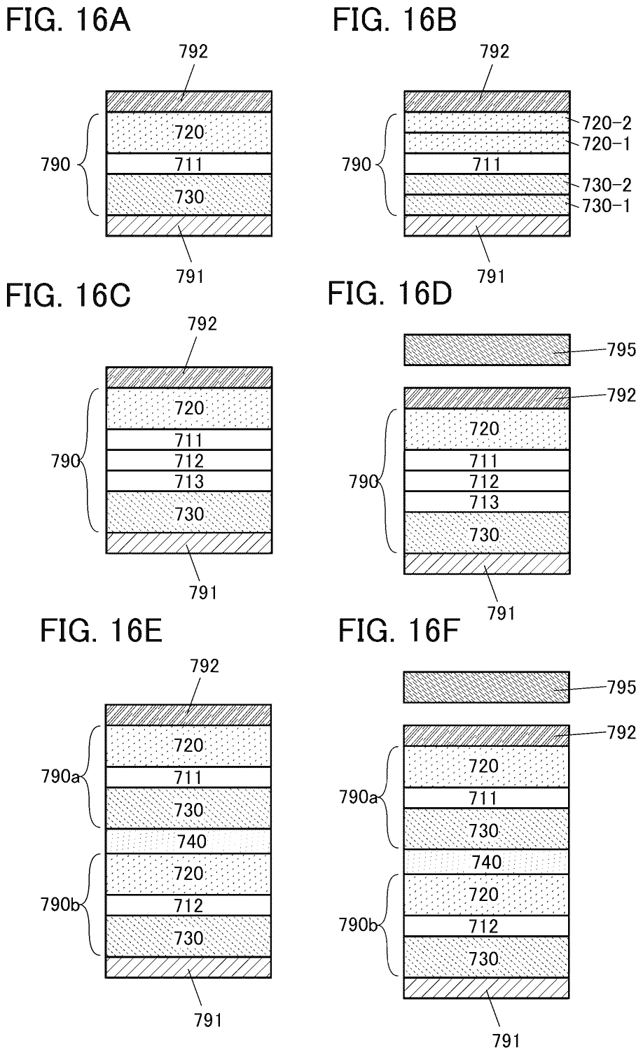

As illustrated in FIG. 16A, the light-emitting device includes an EL layer 790 between a pair of electrodes (a lower electrode 791 and an upper electrode 792). The EL layer 790 can be formed of a plurality of layers such as a layer 720, a light-emitting layer 711, and a layer 730. The layer 720 can include, for example, a layer containing a substance with a high electron-injection property (an electron-injection layer), a layer containing a substance with a high electron-transport property (an electron-transport layer), and the like. The light-emitting layer 711 contains a light-emitting compound, for example. The layer 730 can include a layer containing a substance having a high hole-injection property (a hole-injection layer) and a layer containing a substance having a high hole-transport property (a hole-transport layer), for example.

The structure including the layer 720, the light-emitting layer 711, and the layer 730 that are provided between a pair of electrodes can function as a single light-emitting unit, and the structure in FIG. 16A is referred to as a single structure in this specification.

Specifically, a light-emitting device illustrated in FIG. 16B includes, over the lower electrode 791, a layer 730-1, a layer 730-2, the light-emitting layer 711, a layer 720-1, a layer 720-2, and the upper electrode 792. For example, the lower electrode 791 functions as an anode, and the upper electrode 792 functions as a cathode. In that case, the layer 730-1 functions as a hole-injection layer, the layer 730-2 functions as a hole-transport layer, the layer 720-1 functions as an electron-transport layer, and the layer 720-2 functions as an electron-injection layer. In contrast, when the lower electrode 791 functions as a cathode and the upper electrode 792 functions as an anode, the layer 730-1 functions as an electron-injection layer, the layer 730-2 functions as an electron-transport layer, the layer 720-1 functions as a hole-transport layer, and the layer 720-2 functions as a hole-injection layer. With such a layer structure, carriers can be efficiently injected to the light-emitting layer 711, and the efficiency of recombination of carriers in the light-emitting layer 711 can be increased.

Note that the structures in which a plurality of light-emitting layers (light-emitting layers 711, 712, and 713) are provided between the layer 720 and the layer 730 as illustrated in FIG. 16C and FIG. 16D are also variations of the single structure.

A structure in which a plurality of light-emitting units (an EL layer 790a and an EL layer 790b) are connected in series with an intermediate layer (a charge-generation layer) 740 therebetween as illustrated in FIG. 16E and FIG. 16F is referred to as a tandem structure in this specification. The tandem structure may be referred to as a stack structure. Note that the tandem structure enables a light-emitting device capable of high luminance light emission.

In FIG. 16C, light-emitting materials that emit light of the same color or the same light-emitting material may be used for the light-emitting layer 711, the light-emitting layer 712, and the light-emitting layer 713. The stacked light-emitting layers can increase emission luminance.

Alternatively, different light-emitting materials may be used for the light-emitting layer 711, the light-emitting layer 712, and the light-emitting layer 713. White light emission can be obtained when the light-emitting layer 711, the light-emitting layer 712, and the light-emitting layer 713 emit light having a relationship of complementary colors. FIG. 16D illustrates an example in which a coloring layer 795 functioning as a color filter is provided. When white light passes through a color filter, light of a desired color can be obtained.

In addition, in FIG. 16E, light-emitting materials that emit light of the same color may be used for the light-emitting layer 711 and the light-emitting layer 712. Alternatively, light-emitting materials that emit light of different colors may be used for the light-emitting layer 711 and the light-emitting layer 712. White light emission can be obtained when the light-emitting layer 711 and the light-emitting layer 712 emit light having a relationship of complementary colors. FIG. 16F illustrates an example in which the coloring layer 795 is further provided.

Note that also in FIG. 16C, FIG. 16D, FIG. 16E, and FIG. 16F, the layer 720 and the layer 730 may each have a stacked-layer structure of two or more layers as illustrated in FIG. 16B.

In addition, in FIG. 16D, light-emitting materials that emit light of the same color may be used for the light-emitting layer 711, the light-emitting layer 712, and the light-emitting layer 713. Similarly, in FIG. 16F, light-emitting materials that emit light of the same color may be used for the light-emitting layer 711 and the light-emitting layer 712. In that case, when a color conversion layer is employed instead of the coloring layer 795, light of a desired color that is different from the color of the light-emitting material can be obtained. For example, a blue light-emitting material is used for each light-emitting layer and blue light passes through the color conversion layer, so that light with a wavelength longer than that of blue light (e.g., red light, green light, or the like) can be obtained. For the color conversion layer, a fluorescent material, a phosphorescent material, quantum dots, or the like can be used.

The emission color of the light-emitting device can be red, green, blue, cyan, magenta, yellow, white, or the like depending on the material that constitutes the EL layer 790. In addition, when the light-emitting device has a microcavity structure, color purity can be further increased.

In the light-emitting device that emits white light, a light-emitting layer may contain two or more kinds of light-emitting substances, or two or more light-emitting layers containing different light-emitting substances may be stacked. In such a case, the light-emitting substances are preferably selected such that the light-emitting substances emit light having a relationship of complementary colors.

### [Light-Emitting Device]

A specific structure example of the light-emitting device is described here.

The light-emitting device includes at least the light-emitting layer. In addition, the light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like.

Either a low molecular compound or a high molecular compound can be used in the light-emitting device, and an inorganic compound may also be included. Each layer included in the light-emitting device can be formed by a method such as an evaporation method (including a vacuum evaporation method), a transfer method, a printing method, an inkjet method, or a coating method.

For example, the light-emitting device can include one or more of a hole-injection layer, a hole-transport layer, a hole-blocking layer, an electron-blocking layer, an electron-transport layer, and an electron-injection layer.

The hole-injection layer is a layer injecting holes from an anode to a hole-transport layer and containing a material with a high hole-injection property. Examples of a material with a high hole-injection property include an aromatic amine compound, and a composite material containing a hole-transport material and an acceptor material (an electron-accepting material).

The hole-transport layer is a layer transporting holes, which are injected from the anode by the hole-injection layer, to the light-emitting layer. The hole-transport layer is a layer containing a hole-transport material. The hole-transport material preferably has a hole mobility of higher than or equal to 1×10⁻⁶ cm²/Vs. Note that other substances can be also used as long as the substances have a hole-transport property higher than an electron-transport property. As the hole-transport material, a material with a high hole-transport property, such as a T-electron rich heteroaromatic compound (e.g., a carbazole derivative, a thiophene derivative, or a furan derivative) or an aromatic amine (a compound having an aromatic amine skeleton) is preferable.

The electron-transport layer is a layer transporting electrons, which are injected from the cathode by the electron-injection layer, to the light-emitting layer. The electron-transport layer contains an electron-transport material. The electron-transport material preferably has an electron mobility of higher than or equal to 1×10⁻⁶ cm²/Vs. Note that other substances can be also used as long as the substances have an electron-transport property higher than a hole-transport property. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a Tc-electron deficient heteroaromatic compound including a nitrogen-containing heteroaromatic compound.

The electron-injection layer is a layer injecting electrons from the cathode to the electron-transport layer and containing a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can be also used.

For the electron-injection layer, for example, an alkali metal, an alkaline earth metal, or a compound thereof, such as lithium, cesium, ytterbium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate can be used. In addition, the electron-injection layer may have a stacked-layer structure of two or more layers. In the stacked-layer structure, for example, lithium fluoride can be used for a first layer and ytterbium can be provided for a second layer.

Alternatively, as the above electron-injection layer, an electron-transport material may be used. For example, a compound having an unshared electron pair and having an electron deficient heteroaromatic ring can be used as the electron-transport material. Specifically, a compound having at least one of a pyridine ring, a diazine ring (a pyrimidine ring, a pyrazine ring, or a pyridazine ring), and a triazine ring can be used.

Note that the lowest unoccupied molecular orbital (LUMO) level of the organic compound having an unshared electron pair is preferably greater than or equal to −3.6 eV and less than or equal to −2.3 eV. In addition, in general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-α:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

The light-emitting layer is a layer containing a light-emitting substance. The light-emitting layer can contain one or more kinds of light-emitting substances. As the light-emitting substance, a substance that exhibits an emission color of blue, violet, bluish violet, green, yellowish green, yellow, orange, red, or the like is used as appropriate. Alternatively, a substance that emits near-infrared light can be used as the light-emitting substance.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (a host material, an assist material, and the like) in addition to the light-emitting substance (a guest material). As one or more kinds of organic compounds, one or both of a hole-transport material and an electron-transport material can be used. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength is to overlap with the wavelength of the lowest-energy-side absorption band of the light-emitting substance, energy can be transferred smoothly and light emission can be obtained efficiently. With this structure, the high efficiency, low-voltage driving, and long lifetime of the light-emitting device can be achieved at the same time.

At least part of the structure examples, the drawings corresponding thereto, and the like described in this embodiment can be combined with the other structure examples, the other drawings, and the like as appropriate.

At least part of this embodiment can be implemented in appropriate combination with the other embodiments described in this specification.

### Embodiment 5

In this embodiment, a light-receiving device that can be used in the display device according to one embodiment of the present invention and a display device having a function of receiving and emitting light will be described.

For example, a pn-type or pin-type photodiode can be used as the light-receiving device. The light-receiving device functions as a photoelectric conversion device (also referred to as a photoelectric conversion element) that detects light entering the light-receiving device and generates charge. The amount of charge generated from the light-receiving device depends on the amount of light entering the light-receiving device.

It is particularly preferable to use an organic photodiode including a layer containing an organic compound, as the light-receiving device. An organic photodiode, which is easily made thin, lightweight, and large in area and has a high degree of freedom for shape and design, can be employed in a variety of display devices.

### [Light-Receiving Device]

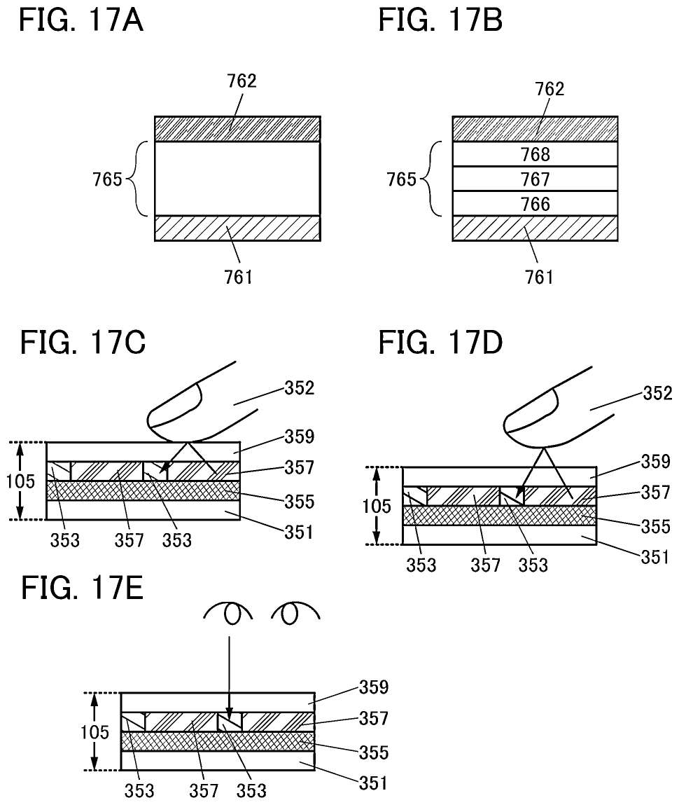

As illustrated in FIG. 17A, the light-receiving device includes a layer 765 between a pair of electrodes (a lower electrode 761 and an upper electrode 762). The layer 765 includes at least one active layer, and may further include another layer.

In addition, FIG. 17B is a modification example of the layer 765 included in the light-receiving device illustrated in FIG. 17A. Specifically, the light-receiving device illustrated in FIG. 17B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. In addition, the layer 768 includes one or both of an electron-transport layer and a hole-blocking layer. In the case where the lower electrode 761 is a cathode and the upper electrode 762 is an anode, the structures of the layer 766 and the layer 768 are interchanged.

Here, the display device according to one embodiment of the present invention includes a layer shared by the light-receiving device and the light-emitting device (the layer can be also regarded as a continuous layer shared by the light-receiving device and the light-emitting device) in some cases. The function of such a layer in the light-emitting device is different from its function in the light-receiving device in some cases. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. In addition, a layer shared by the light-receiving device and the light-emitting device might have the same function in the light-emitting device and the light-receiving device. The hole-transport layer functions as a hole-transport layer in both the light-emitting device and the light-receiving device, and the electron-transport layer functions as an electron-transport layer in both the light-emitting device and the light-receiving device.

Next, materials that can be used for the light-receiving device are described.

Either a low molecular compound or a high molecular compound can be used in the light-receiving device, and an inorganic compound may be contained. Each layer included in the light-receiving device can be formed by an evaporation method (including a vacuum evaporation method), a transfer method, a printing method, an inkjet method, a coating method, or the like.

The active layer included in the light-receiving device contains a semiconductor. Examples of the semiconductor include an inorganic semiconductor such as silicon and an organic semiconductor including an organic compound. This embodiment describes an example in which an organic semiconductor is used as the semiconductor contained in the active layer. The use of an organic semiconductor is preferable because the light-emitting layer and the active layer can be formed by the same method (e.g., a vacuum evaporation method) and thus a manufacturing apparatus can be used in common.

Examples of an n-type semiconductor material contained in the active layer include electron-accepting organic semiconductor materials such as fullerene (e.g., C₆₀, C₇₀, or the like) and fullerene derivatives. Examples of fullerene derivatives include [6,6]-phenyl-C₇₁-butyric acid methyl ester (abbreviation: PC70BM), [6,6]-phenyl-C₆₁-butyric acid methyl ester (abbreviation: PC60BM), and 1′,1″,4′,4″-tetrahydro-di[1,4]methanonaphthaleno[1,2:2′,3′,56,60:2″,3″ ][5,6]fullerene-C₆₀ (abbreviation: ICBA).

Other examples of the n-type semiconductor material include perylenetetracarboxylic acid derivatives such as N,N-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl)bis(methan-1-yl-1-ylidene)dimalononitrile (abbreviation: FT2TDMN).

Other examples of the n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Other examples of the p-type semiconductor material include a carbazole derivative, a thiophene derivative, a furan derivative, and a compound having an aromatic amine skeleton. Furthermore, other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase a carrier-transport property.

In addition, for the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

In addition, three or more kinds of materials may be mixed for the active layer. For example, a third material may be mixed with an n-type semiconductor material and a p-type semiconductor material in order to extend a wavelength range. In that case, the third material may be either a low molecular compound or a high molecular compound.

As a layer other than the active layer, the light-receiving device may further include a layer containing a substance with a high hole-transport property, a substance with a high electron-transport property, a substance with a bipolar property (a substance with a high electron-transport property and a high hole-transport property), or the like. Furthermore, without limitation to the above, a layer containing a substance with a high hole-injection property, a hole-blocking material, a material with a high electron-injection property, an electron-blocking material, or the like may be further included. A material that can be used for the light-emitting device can be used for layers other than the active layer included in the light-receiving device.

As the hole-transport material or the electron-blocking material, a high molecular compound such as poly(3,4-ethylenedioxythiophene)/poly(styrenesulfonic acid) (PEDOT/PSS), or an inorganic compound such as a molybdenum oxide or copper iodide (CuI) can be used, for example. In addition, as the electron-transport material or the hole-blocking material, an inorganic compound such as zinc oxide (ZnO) or an organic compound such as polyethylenimine ethoxylate (PEIE) can be used. The light-receiving device may include a mixed film of PEIE and ZnO, for example.

### [Display Apparatus Having Light Detection Function]

In the display apparatus according to one embodiment of the present invention, the light-emitting devices are arranged in a matrix in a display portion, and an image can be displayed on the display portion. Furthermore, the light-receiving devices are arranged in a matrix in the display portion, and the display portion has one or both of an imaging function and a sensing function in addition to an image displaying function. The display portion can be used as an image sensor or a touch sensor. That is, by detecting light with the display portion, an image can be captured or the approach or contact of a target (a finger, a hand, a pen, or the like) can be detected.

Furthermore, in the display apparatus according to one embodiment of the present invention, the light-emitting device can be used as a light source of the sensor. In the display apparatus according to one embodiment of the present invention, when an object reflects (or scatters) light emitted from the light-emitting device included in the display portion, the light-receiving device can detect reflected light (or scattered light); thus, imaging or touch detection is possible even in a dark place.

Accordingly, neither a light-receiving portion nor a light source does not need to be provided separately from the display apparatus, and thus the number of components of an electronic device can be reduced. For example, it is not necessary to separately provide a biometric authentication device provided in the electronic device or a capacitive touch panel for scrolling or the like. Thus, with the use of the display apparatus according to one embodiment of the present invention, the electronic device can be provided with reduced manufacturing cost.

Specifically, the display apparatus according to one embodiment of the present invention includes a light-emitting device and a light-receiving device in a pixel. In the display apparatus according to one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus using the organic EL device.

In the display apparatus including the light-emitting device and the light-receiving device in the pixel, the pixel has a light-receiving function, which enables detection of the touch or approach of an object while an image is displayed. For example, all the subpixels included in the display apparatus can display an image; alternatively, some subpixels can emit light as a light source and the other subpixels can display an image.

In the case where the light-receiving device is used as an image sensor, the display apparatus can capture an image with the use of the light-receiving device. For example, the display apparatus of this embodiment can be used as a scanner.

For example, imaging for personal authentication with the use of a fingerprint, a palm print, an iris, the shape of a blood vessel (including the shape of a vein and the shape of an artery), a face, or the like is possible by using the image sensor.

For example, an image of the periphery of an eye, the surface of the eye, or the inside (fundus or the like) of the eye of a user of a wearable device can be captured with the use of the image sensor. Therefore, the wearable device can have a function of detecting any one or more selected from a blink, movement of an iris, and movement of an eyelid of the user.

In addition, the light-receiving device can be used in a touch sensor (also referred to as a direct touch sensor), a near touch sensor (also referred to as a hover sensor, a hover touch sensor, a contactless sensor, or a touchless sensor), or the like.

Here, a touch sensor or a near touch sensor can detect the approach or touch of an object (a finger, a hand, a pen, or the like).

The touch sensor can detect an object when the display apparatus and the object come in direct contact with each other. In addition, the near touch sensor can detect an object even when the object is not in contact with the display apparatus. For example, the display apparatus is preferably capable of detecting an object when the distance between the display apparatus and the object is greater than or equal to 0.1 mm and less than or equal to 300 mm, preferably greater than or equal to 3 mm and less than or equal to 50 mm. This structure enables the display apparatus to be operated without direct contact of the object, that is, enables the display apparatus to be operated in a contactless (touchless) manner. With the above structure, the display apparatus can have a reduced risk of being dirty or damaged, or can be operated without the object directly touching a dirt (e.g., dust or a virus) attached to the display apparatus.

In addition, the refresh rate of the display apparatus according to one embodiment of the present invention can be variable. For example, the refresh rate is adjusted (adjusted in the range from 1 Hz to 240 Hz, for example) in accordance with contents displayed on the display apparatus, so that power consumption can be reduced. Furthermore, the drive frequency of the touch sensor or the near touch sensor may be changed in accordance with the refresh rate. In the case where the refresh rate of the display apparatus is 120 Hz, for example, a structure can be employed in which the drive frequency of the touch sensor or the near touch sensor is a frequency higher than 120 Hz (typically 240 Hz). This structure can achieve low power consumption and can increase the response speed of the touch sensor or the near touch sensor.

A display apparatus 105 illustrated in FIG. 17C to FIG. 17E includes layers 353 each including a light-receiving device, a functional layer 355, and layers 357 each including a light-emitting device, between a substrate 351 and a substrate 359.

The functional layer 355 includes a circuit for driving a light-receiving device and a circuit for driving a light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure provided with neither a switch nor a transistor may be employed.

For example, when light emitted from the light-emitting device in the layer 357 including the light-emitting device is reflected by a finger 352 touching the display apparatus 105 as illustrated in FIG. 17C, the light-receiving device in the layer 353 including the light-receiving device detects the reflected light. Thus, the touch of the finger 352 on the display apparatus 105 can be detected.

Alternatively, as illustrated in FIG. 17D and FIG. 17E, the display apparatus may have a function of detecting an object that is close to (i.e., not touching) the display apparatus or capturing an image of such an object.

At least part of this embodiment can be implemented in appropriate combination with the other embodiments described in this specification.

### Embodiment 6

In this embodiment, display panels according to one embodiment of the present invention will be described.

One embodiment of the present invention is a display panel capable of increasing its size by arranging a plurality of display panels to partly overlap with one another. In addition, in two display panels overlapping with each other, at least a display panel positioned on the display surface side (upper side) includes a portion transmitting visible light that is adjacent to a display portion. A pixel of a display panel positioned on the lower side and the portion transmitting visible light of the display panel positioned on the upper side are provided to overlap with each other. Thus, the two display panels can display a seamless contiguous image when seen from the display surface side (in a plan view).

For example, the display panel according to one embodiment of the present invention is a stacked-layer panel including a first display panel and a second display panel. The first display panel includes a first region, and the first region includes a first pixel and a second pixel. The second display panel includes a second region, a third region, and a fourth region. The second region includes a third pixel. The third region has a function of transmitting visible light. The fourth region has a function of blocking visible light. In addition, the second pixel of the first display panel and the third region of the second display panel have a region where they overlap with each other. Furthermore, the aperture ratio of the second pixel is preferably higher than the aperture ratio of the first pixel.

For one or both of the first display panel and the second display panel, the display device described above as an example that includes a light-emitting element and a light-receiving element can be used. In other words, it is also possible to say that at least one of the first pixel, the second pixel, and the third pixel includes a light-emitting element and a light-receiving element.

More specifically, the following structure can be employed, for example.

### Structure Example 1

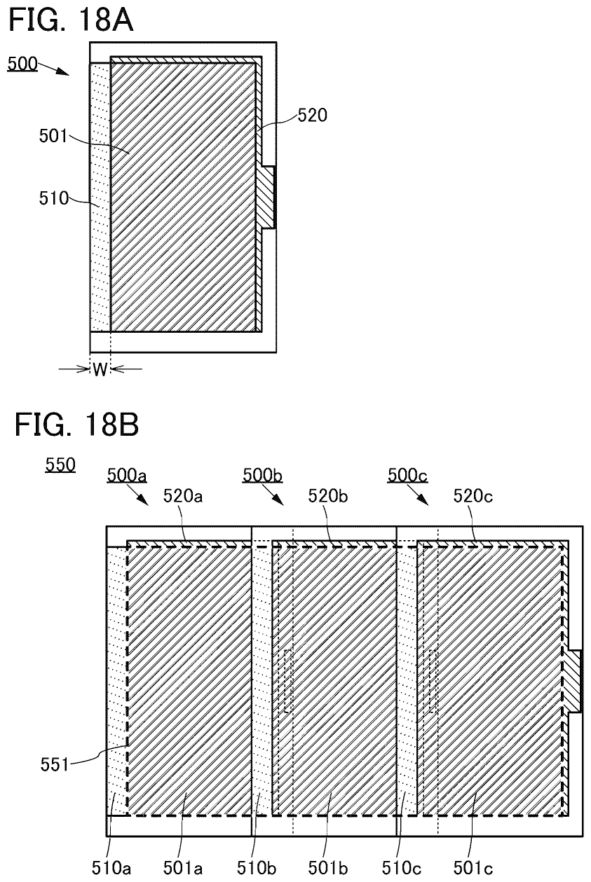

FIG. 18A is a schematic top view of a display panel 500 included in the display panel according to one embodiment of the present invention. As the structure of the display panel 500, the structure of the display device 100 described in the above embodiment can be employed.

The display panel 500 includes a display portion 501, and a region 510 transmitting visible light and a region 520 having a portion blocking visible light that are adjacent to the display portion 501.

Here, the display panel 500 alone can display an image on the display portion 501. Moreover, the display panel 500 alone can take an image with the display portion 501.

In the region 510, for example, a pair of substrates included in the display panel 500 and a sealant or the like for sealing a display element sandwiched between the pair of substrates may be provided. In that case, a material having a property of transmitting visible light is used for a member provided in the region 510. The width of the region 510 is denoted by W.

A wiring electrically connected to pixels included in the display portion 501 is provided in the region 520, for example. In addition to such a wiring, a driver circuit (a scan line driver circuit, a signal line driver circuit, or the like) for driving the pixels or a circuit such as a protection circuit may be provided. Furthermore, the region 520 includes a region where a terminal electrically connected to an external terminal or a wiring layer (such a terminal is also referred to as a connection terminal), a wiring electrically connected to the terminal, and the like are provided.

FIG. 18B is a schematic top view illustrating a structure example of a display panel 550 including the display panels 500 illustrated in FIG. 18A. FIG. 18B illustrates an example in which the display panel 550 includes three display panels 500.

Note that in this embodiment, in the case where a description is made by distinguishing the display panels from each other, distinguishing components included in the display panels from each other, or distinguishing components relating to the display panels from each other, alphabets are added to their reference numerals. In addition, unless otherwise specified, in a plurality of display panels partly overlapping with each other, the letter symbol “a” might be added to reference numerals for a display panel placed on the lowest side (a side opposite to the display surface side), components thereof, and the like, and alphabets might be added to reference numerals of one or more display panels sequentially placed thereover in alphabetical order. Furthermore, unless otherwise specified, even in the case of describing a structure where a plurality of display panels are provided, a description is made without any alphabets when a common part of the display panels, the components, or the like is described.

The display panel 550 illustrated in FIG. 18B includes a display panel 500a, a display panel 500b, and a display panel 500c.

The display panel 500b is placed so that part of the display panel 500b is stacked over an upper side (a display surface side) of the display panel 500a. Specifically, the display panel 500b is placed so that a display portion 501a of the display panel 500a and a region 510b transmitting visible light of the display panel 500b overlap with each other and that the display portion 501a of the display panel 500a and a region 520b blocking visible light of the display panel 500b do not overlap each other.

Furthermore, the display panel 500c is placed so that part of the display panel 500c is stacked over an upper side (a display surface side) of the display panel 500b. Specifically, the display panel 500c is placed so that a display portion 501b of the display panel 500b and a region 510c transmitting visible light of the display panel 500c overlap with each other and that the display portion 501b of the display panel 500b and a region 520c blocking visible light of the display panel 500c do not overlap each other.

The region 510b transmitting visible light overlaps with the display portion 501a; thus, the whole display portion 501a can be visually recognized from the display surface side. Similarly, the whole display portion 501b can also be visually recognized from the display surface side when the region 510c overlaps with the display portion 501b. Therefore, a region where the display portion 501a, the display portion 501b, and a display portion 501c are placed seamlessly can serve as a display portion 551 of the display panel 550.

The display portion 551 of the display panel 550 can be enlarged by the number of display panels 500. In that case, by using display panels each having an imaging function (i.e., display panels each including a light-emitting element and a light-receiving element) as all the display panels 500, the entire display portion 551 can serve as an imaging region.

### Structure Example 2

FIG. 18B illustrates the structure where a plurality of display panels 500 are placed to overlap with one another in one direction; however, the plurality of display panels 500 may be placed to overlap with one another in two directions of a vertical direction and a horizontal direction.

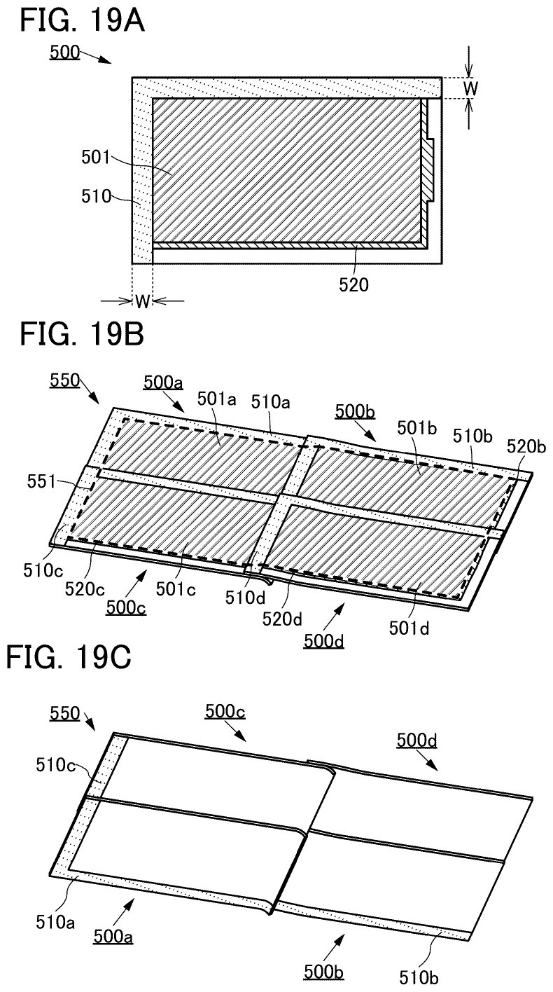

FIG. 19A is a schematic top view illustrating an example of the display panel 500 in which the shape of the region 510 is different from that in FIG. 18A. In the display panel 500 illustrated in FIG. 19A, the region 510 transmitting visible light is placed along two sides of the display portion 501.

FIG. 19B is a schematic perspective view of the display panel 550 in which the display panels 500 illustrated in FIG. 19A are arranged two by two in the vertical and horizontal directions. FIG. 19C is a schematic perspective view of the display panel 550 when seen from a side opposite to the display surface side.

In FIG. 19B and FIG. 19C, a region along a short side of the display portion 501a of the display panel 500a and part of the region 510b of the display panel 500b are provided to overlap each other. In addition, a region along a long side of the display portion 501a of the display panel 500a and part of the region 510c of the display panel 500c are provided to overlap each other. Moreover, a region 510d of a display panel 500d is provided to overlap with a region along a long side of the display portion 501b of the display panel 500b and a region along a short side of the display portion 501c of the display panel 500c.

Therefore, as illustrated in FIG. 19B, a region where the display portion 501a, the display portion 501b, the display portion 501c, and the display portion 501d are placed seamlessly can serve as the display portion 551 of the display panel 550.

Here, it is preferable that a flexible material be used for the pair of substrates used in the display panel 500 and that the display panel 500 have flexibility. Thus, as illustrated in FIG. 19B and FIG. 19C, for example, part of the display panel 500a can be bent and placed to overlap with a lower side of the display portion 501b of the adjacent display panel 500b.

Moreover, when each display panel 500 has flexibility, the display panel 500b can be bent gently so that a top surface of the display portion 501b of the display panel 500b and a top surface of the display portion 501a of the display panel 500a are equal to each other in height. Thus, the display regions can have uniform height except in the vicinity of a region where the display panel 500a and the display panel 500b overlap with each other, and the display quality of an image displayed on the display portion 551 of the display panel 550 can be increased.

Although the relationship between the display panel 500a and the display panel 500b is taken as an example in the above description, the same applies to relationship between two adjacent display panels.

In addition, to reduce a step between two adjacent display panels 500, the thickness of the display panel 500 is preferably small. For example, the thickness of the display panel 500 is preferably less than or equal to 1 mm, further preferably less than or equal to 300 μm, still further preferably less than or equal to 100 μm.

Furthermore, a substrate for protecting the display portion 551 of the display panel 550 may be provided. In that case, the substrate may be provided for each display panel, or one substrate may be provided for a plurality of display panels.

Note that although the structure where the four rectangular display panels 500 are stacked is described here, an extremely large stacked-layer panel can be obtained by increasing the number of display panels 500. In addition, by changing a method for arranging the plurality of display panels 500, the contour shape of the display portion of the stacked-layer panel can be a non-rectangular shape, e.g., a variety of shapes such as a circular shape, an elliptical shape, and a polygonal shape. Furthermore, by arranging the display panels 500 three-dimensionally, a stacked-layer panel including a display portion having a three-dimensional shape, e.g., a circular cylindrical shape, a spherical shape, a hemispherical shape, or the like can be achieved.

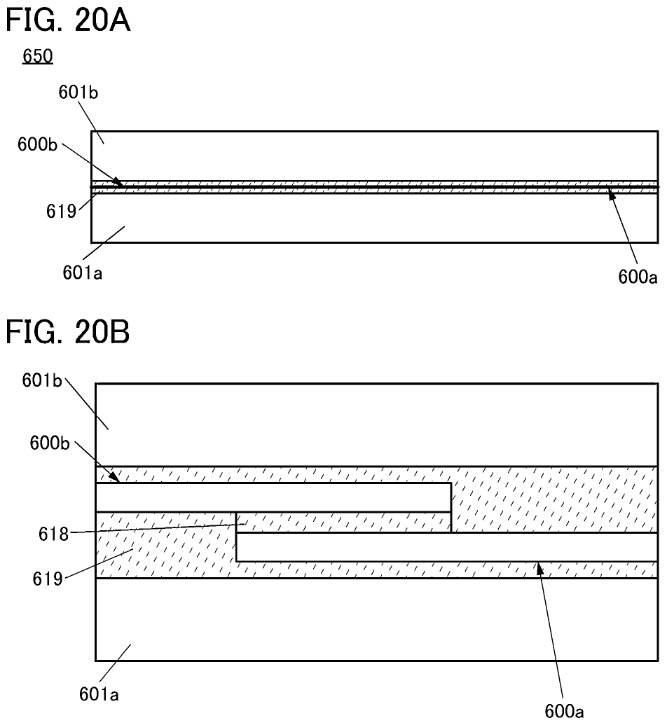

FIG. 20A is a cross-sectional view illustrating a structure example of a display panel 650 according to one embodiment of the present invention. The display panel 650 can have a structure in which a display panel 600a and a display panel 600b are sandwiched between a substrate 601a and a substrate 601b and a space between the substrate 601a and the substrate 601b is filled with an adhesive layer 619.

For the substrate 601a and the substrate 601b, it is possible to use a polyester resin such as polyethylene terephthalate (PET) or polyethylene naphthalate (PEN); a polyacrylonitrile resin; an acrylic resin; a polyimide resin; a polymethyl methacrylate resin; a polycarbonate (PC) resin; a polyethersulfone (PES) resin; a polyamide resin (nylon, aramid, or the like); a polysiloxane resin; a cycloolefin resin; a polystyrene resin; a polyamide-imide resin; a polyurethane resin; a polyvinyl chloride resin; a polyvinylidene chloride resin; a polypropylene resin; a polytetrafluoroethylene (PTFE) resin; an ABS resin; cellulose nanofiber; or the like. A variety of curable adhesives such as a reactive curable adhesive, a thermosetting curable adhesive, an anaerobic adhesive, and a photocurable adhesive such as an ultraviolet curable adhesive can be used for the adhesive layer 619. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. Alternatively, a two-liquid-mixture-type resin may be used. Alternatively, an adhesive sheet or the like may be used.

As each of the structures of the display panel 600a and the display panel 600b, the structure of the display device 100 described in the above embodiment can be employed. In addition, the display panel 600 preferably has flexibility like the display panel 500.

FIG. 20B is an enlarged view of the structure illustrated in FIG. 20A. As illustrated in FIG. 20B, an end portion of the display panel 600a and an end portion of the display panel 600b are attached to each other with an adhesive layer 618 to overlap with each other. Specifically, an end portion of a display portion of the display panel 600a and an end portion of a display portion of the display panel 600b are attached to each other with the adhesive layer 618 to overlap with each other. In other words, the display panel 650 can have a structure in which the display panel 600a and the display panel 600b are stacked. For the adhesive layer 618, a material similar to the material that can be used for the adhesive layer 619 can be used.

With a structure in which a plurality of display panels 600 are stacked, the display panel 650 can be a large-sized display panel like the display panel 600. Alternatively, the display panel 650 may have a structure in which three or more display panels 600 are stacked. By increasing the number of display panels 600 included in the display panel 650, the size of the display panel 650 can be further increased.

At least part of the structure examples, the drawings corresponding thereto, and the like described in this embodiment can be combined with the other structure examples, the other drawings, and the like as appropriate.

At least part of this embodiment can be implemented in appropriate combination with the other embodiments described in this specification.

### Example 1

In this example, results of a manufactured display device according to one embodiment of the present invention will be described. A display device manufactured in this example is a kawara-type multidisplay.

### <Display Panel>

First, the details of a display panel used in the display device manufactured in this example are described.

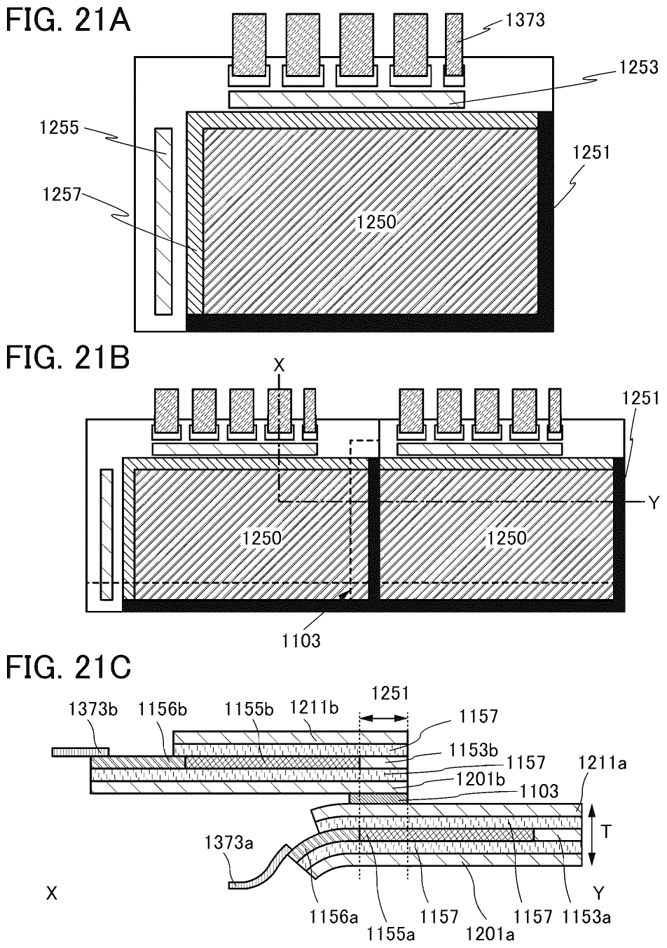

FIG. 21A illustrates a schematic view of the display panel in this example. The display panel illustrated in FIG. 21A is an active matrix organic EL display that has a light-emitting portion 1250 with a diagonal size of 13.5 inches, 1280×720 effective pixels, and a definition of 108 ppi. The display panel includes a demultiplexer (DeMUX) 1253 that functions as a source driver. In addition, the display panel further includes a scan driver 1255. Two sides of the light-emitting portion 1250 are in contact with a region 1251 transmitting visible light. A lead wiring 1257 is provided around the other two sides.

As a transistor included in the display panel, a channel-etched type transistor including a CAAC-OS (a c-axis aligned crystalline oxide semiconductor) was employed. An In—Ga—Zn-based oxide was used as the CAAC-OS.

A tandem (stacked-layer) type organic EL element that emits white light was used as a light-emitting element. The light-emitting element has a top-emission structure, and light from the light-emitting element is extracted to the outside of the display panel through a color filter.

FIG. 21B illustrates a schematic view of the display device when two display panels are arranged in a horizontal direction. In addition, FIG. 21C illustrates a schematic cross-sectional view taken along the dashed dotted line X-Y of the display device illustrated in FIG. 21B.

The display device in this example is formed by overlapping a plurality of display panels so that a non-display region between display regions is small. Specifically, a light-transmitting layer 1103 is provided between the region 1251 transmitting visible light of an upper display panel and the light-emitting portion 1250 of a lower display panel.

On two sides of the display panel, a component blocking visible light, such as a lead wiring or a driver, is not provided at all from an end portion of the light-emitting portion 1250 to an end portion of the display panel, and there is the region 1251 transmitting visible light. The width of the region 1251 transmitting visible light in the display panel is small, and the thickness T of the region 1251 transmitting visible light (also referred to as the thickness of one display panel) is very small. Therefore, although the display device in this example has a portion where the display panels overlap with each other, a step formed on the display surface side is extremely small and thus a seam is less noticeable.

Four display panels have flexibility. For example, as illustrated in FIG. 21C, the vicinity of an FPC 1373a of the lower display panel can be bent, and part of the lower display panel and part of the FPC 1373a can be placed under the light-emitting portion 1250 of the upper display panel adjacent to the FPC 1373a. As a result, the FPC 1373a can be placed without physical interference with a rear surface of the upper display panel. Consequently, other display panels can be provided on four sides of the display panel, so that the area is easily increased.

In this example, an adsorption film including adsorption layers on both surfaces of a base material was used as the light-transmitting layer 1103. With the use of the adsorption film, two display panels included in the display device can be detachably attached to each other. An adsorption layer on one surface of the light-transmitting layer 1103 is adsorbed on a substrate 121 la, and an adsorption layer on the other surface of the light-transmitting layer 1103 is adsorbed on a substrate 1201b.

In FIG. 21B, the light-transmitting layer 1103 includes not only a portion overlapping with the region 1251 transmitting visible light, but also a portion overlapping with the light-emitting portion 1250. In FIG. 21C, the light-transmitting layer 1103 overlaps with the entire region 1251 transmitting visible light from an end portion of the substrate 1201b, and also overlaps with part of a region 1155b including a display element. Note that the light-transmitting layer 1103 is not provided on a curved portion of the display panel that is close to a portion to which the FPC 1373a is connected in FIG. 21C. However, the light-transmitting layer 1103 may be provided on the curved portion of the display panel depending on the thickness or the level of flexibility of the light-transmitting layer 1103.

Each of the display panels was manufactured by attaching a substrate and an element layer to each other with an adhesive layer. For example, as illustrated in FIG. 21C, a substrate 1201a, the substrate 1211a, the substrate 1201b, and a substrate 121 lb are attached to an element layer 1153a, the element layer 1153a, an element layer 1153b, and the element layer 1153b, respectively, with an adhesive layer 1157. The element layer 1153a has a region 1155a including a display element and a region 1156a including a wiring electrically connected to the display element. Similarly, the element layer 1153b has the region 1155b including a display element and a region 1156b including a wiring electrically connected to the display element.

### <Display Device>

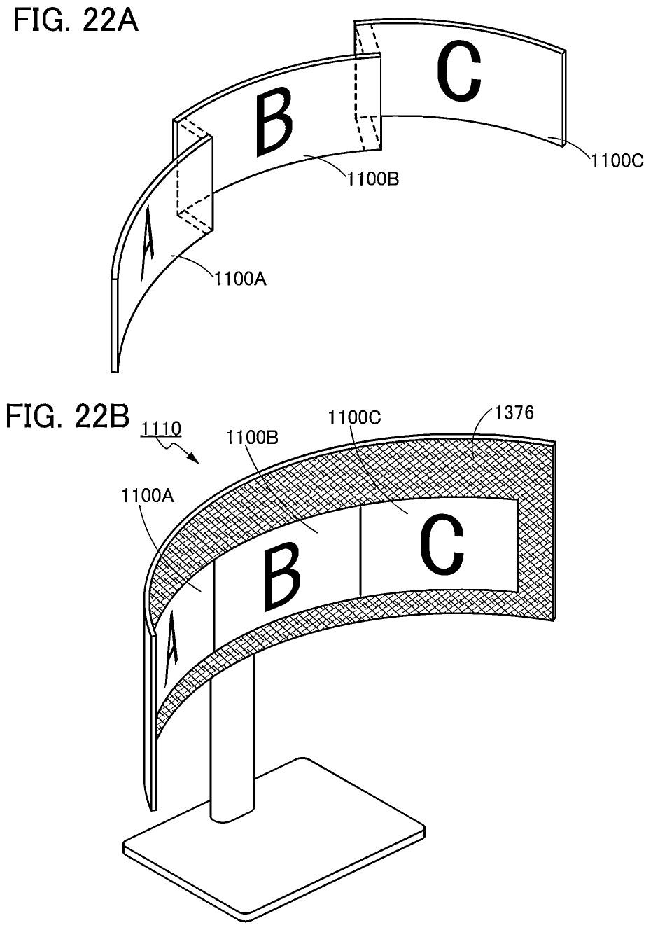

FIG. 22A and FIG. 22B are diagrams illustrating a display device where three display panels illustrated in FIG. 21A are arranged in a horizontal direction.

FIG. 22A is a diagram showing a state where three display panels described in FIG. 21A to FIG. 21C are arranged in the horizontal direction. When a display panel 1100A overlaps with part of a display panel 1100B and the display panel 1100B overlaps with part of a display panel 1100C, display can be performed seamlessly in the display panel 1100A, the display panel 1100B, and the display panel 1100C. Note that FIG. 22A illustrates a structure where the display panel 1100A, the display panel 1100B, and the display panel 1100C are bent so that each display surface is a concave surface; however, the display panel 1100A, the display panel 1100B, and the display panel 1100C can be bent so that each display surface is a convex surface.

FIG. 22B is a schematic bird's eye view of a display device 1110 where three display panels are arranged in the horizontal direction as illustrated in FIG. 22A. In the display device 1110, the display panels 1100A and 11001B, and the display panel 1100C are attached to one surface of a support 1376. The support 1376, the display panels 1100A and 11001B, and the display panel 1100C are fixed in a bent shape so that a radius of curvature R is 900 mm, which indicates that their design provides a high sense of immersion when viewing.

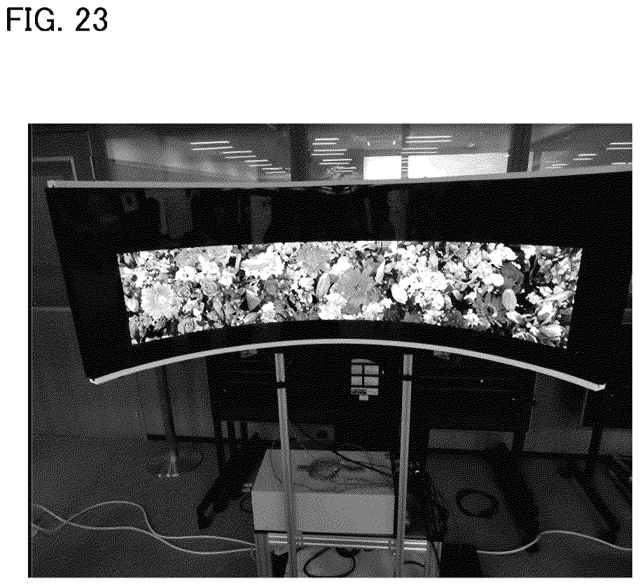

FIG. 23 is a photograph of the appearance of the display device 1110 described with reference to FIG. 22B.

As illustrated in FIG. 23, portions where the three display panels included in the display device 1110 overlap with one another are unnoticeable and seams are not visually recognized easily. Therefore, the three display panels included in the display device 1110 are bent with the radius of curvature R=900 mm and the seams are not visually recognized easily, so that a display device having an extremely high sense of immersion when viewing was able to be manufactured.

### REFERENCE NUMERALS

50: light-blocking device, 51: light-blocking portion, 52: storage portion, 53: display portion, 54: driving means, 55: display panel, 56: reflective layer, 57: spring portion, 58: support portion, 59: roof portion, 60: vehicle, 61: windshield, 62: rear-view mirror, 63: steering wheel, 64: dashboard, 65: opening portion, 66: operating portion, 67: image output portion, 68: image processing portion, 69: transmitting portion, 70: pillar, 71: movable portion, 72: guide portion, 73A: fixing region, 73n: fixing region, 74A: winding portion, 74n: winding portion, 76: shaft portion, 77: rotation mechanism, 78: bearing portion, 91: image, 92: image, 93: image, 94: image, 100: display device, 101: substrate, 110: light-emitting element, 110a: light-emitting element, 110b: light-emitting element, 110B: light-emitting element, 110c: light-emitting element, 110G: light-emitting element, 110R: light-emitting element, 111: pixel electrode, 111B: pixel electrode, 111C: connection electrode, 111G: pixel electrode, 111R: pixel electrode, 112: organic layer, 112n: organic layer, 112G: organic layer, 112R: organic layer, 113: common electrode, 114: common layer, 121: protective layer, 124a: pixel, 124b: pixel, 125: insulating layer, 126: resin layer, 128: layer, 140: connection portion, 150: pixel, 202: transistor, 204: connection portion, 209: transistor, 210: transistor, 211: insulating layer, 212: insulating layer, 214: insulating layer, 215: insulating layer, 218: insulating layer, 221: conductive layer, 222a: conductive layer, 222b: conductive layer, 223: conductive layer, 225: insulating layer, 228: connection portion, 231: semiconductor layer, 231i: channel formation region, 231n: low-resistance region, 242: connection layer, 351: substrate, 352: finger, 353: layer, 355: functional layer, 357: layer, 359: substrate, 400: display device, 411a: conductive layer, 411b: conductive layer, 411c: conductive layer, 412B: EL layer, 412G: EL layer, 413: common electrode, 414: common layer, 416: protective layer, 421: insulating layer, 422: resin layer, 424: layer, 430b: light-emitting element, 430c: light-emitting element, 442: adhesive layer, 451: substrate, 452: substrate, 453: substrate, 454: substrate, 455: adhesive layer, 462: display portion, 464: circuit, 465: wiring, 466: conductive layer, 472: FPC, 473: IC, 500: display panel, 500a: display panel, 500b: display panel, 500c: display panel, 500d: display panel, 501: display portion, 501a: display portion, 501b: display portion, 501c: display portion, 501d: display portion, 510: region, 510b: region, 510c: region, 510d: region, 520: region, 520b: region, 520c: region, 550: display panel, 551: display portion, 600: display panel, 600a: display panel, 600b: display panel, 601a: substrate, 601b: substrate, 618: adhesive layer, 619: adhesive layer, 650: display panel, 711: light-emitting layer, 712: light-emitting layer, 713: light-emitting layer, 720: layer, 720-1: layer, 720-2: layer, 730: layer, 730-1: layer, 730-2: layer, 761: lower electrode, 762: upper electrode, 765: layer, 766: layer, 767: active layer, 768: layer, 790: EL layer, 790a: EL layer, 790b: EL layer, 791: lower electrode, 792: upper electrode, 795: coloring layer, 1100A: display panel, 1100B: display panel, 1100C: display panel, 1103: light-transmitting layer, 1110: display device, 1153a: element layer, 1153b: element layer, 1155a: region, 1155b: region, 1156a: region, 1156b: region, 1157: adhesive layer, 1201a: substrate, 1201b: substrate, 1211a: substrate, 1211b: substrate, 1250: light-emitting portion, 1251: region, 1255: scan driver, 1257: lead wiring, 1373a: FPC, and 1376: support.

1. A light-blocking device comprising:
a light-blocking portion;
a storage portion; and
a driving means,
wherein the light-blocking portion comprises a display portion on facing an inside of a vehicle,
wherein the storage portion is positioned in a roof portion of the vehicle,
wherein the driving means is configured to unfold the light-blocking portion in a first position,
wherein the driving means is configured to unfold the light-blocking portion in a second position,
wherein the driving means is configured to store the light-blocking portion in a third position inside the storage portion,
wherein the first position is a position where the light-blocking portion does not obstruct a driver's forward vision, and
wherein the second position is a position where the light-blocking portion covers 80% or more of an area of a windshield of the vehicle.

2. The light-blocking device according to claim 1,
wherein the light-blocking portion comprises a reflective layer facing the outside of the vehicle,
wherein the reflective layer comprises an aluminum layer and a silicon nitride layer over the aluminum layer, and
wherein reflectance of the reflective layer is higher than or equal to 80%.

3. The light-blocking device according to claim 1,
wherein the light-blocking portion comprises a solar battery facing the outside of the vehicle, and
wherein the solar battery is a silicon-type solar battery, a CIGS-type solar battery, or a perovskite-type solar battery.

4. The light-blocking device according to claim 1,
wherein the display portion is electrically connected to an image output portion,
wherein the image output portion comprises an image processing portion,
wherein the image processing portion is configured to perform correction processing on an image output to the display portion, and
wherein the image processing portion is configured to extend the image in a vertical direction and correct the image into an image with a trapezoidal shape where left-right width of a lower part is wide.

5. The light-blocking device according to claim 1,
wherein the light-blocking portion comprises a spring portion connected to the display portion and a support portion connected to the spring portion,
wherein the support portion is connected to a movable portion comprised in the driving means inside a pillar of the vehicle,
wherein the movable portion is connected to a first winding portion and a second winding portion, and
wherein, when the driving means unfolds the light-blocking portion in the first position or the second position, either one or both of the first winding portion and the second winding portion are configured to perform a rotation operation.

6. The light-blocking device according to claim 5,
wherein the storage portion comprises a transmitting portion, and
wherein the transmitting portion and the display portion overlap with each other when the light-blocking portion is stored in the third position.

7. A light-blocking device comprising:
a light-blocking portion;
a storage portion; and
a driving means,
wherein the storage portion is positioned in a roof portion of a vehicle,
wherein the light-blocking portion comprises a first portion comprising an opening portion, a second portion joined to the first portion, and a third portion joined to the second portion,
wherein a size of the opening portion is larger than a size of a rear-view mirror of the vehicle,
wherein the driving means comprises a first mechanism configured to unfold the light-blocking portion downwards from the roof portion to a lower part in a first state where the first portion, the second portion, and the third portion overlap with one another,
wherein the driving means comprises a second mechanism configured to incline the light-blocking portion while being in the first state substantially parallel to a windshield of the vehicle without contact with the rear-view mirror, and
wherein the driving means comprises a third mechanism configured to unfold the light-blocking portion in an inclined state so that the second portion and the third portion are substantially parallel to the windshield.
